(19) United States
(12) Patent Application Publication
(10) Pub. No.: US 2009/0016862 A1
(43) Pub. Date: Jan. 15, 2009

(54) METHOD AND APPARATUS FOR PROVIDING FLAT PANEL DISPLAY ENVIRONMENTAL ISOLATION

(76) Inventors: Richard H. Gould, Fremont, CA (US); Anthony C. Bonora, Fremont, CA (US); Michael Krolak, Fremont, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/172,084

(22) Filed: Jul. 11, 2008

Related U.S. Application Data
(60) Provisional application No. 60/949,503, filed on Jul. 12, 2007.
(60) Provisional application No. 60/969,570, filed on Aug. 31, 2007.

(51) Int. Cl. H01L 21/02

(52) U.S. Cl. 414/225.01

(57) ABSTRACT

A container for supporting substrates for processing is provided. The container includes a base, a top, and side panels connecting the base and the top. A support structure is disposed in the container. The support structure is configured to support the substrates within the container. The support structure has rows of multiple tensile members extending across a width of the container. Each row of the multiple tensile members is configured to support a substrate, wherein one of the side panels includes a moveable flexible membrane enabling access into the container. A support structure for the flexible membrane includes a synchronization mechanism for synchronizing movement of the flexible membrane with a door of a receiving module of a processing tool or a door of the processing tool.

### CLAIM OF PRIORITY

The present application claims priority under 35 U.S.C. § 119(e) from U.S. Provisional Patent Application No. 60/949,503, filed Jul. 12, 2007, and U.S. Provisional Patent Application No. 60/969,570, filed Aug. 31, 2007, both of which are incorporated by reference in their entirety for all purposes.

### BACKGROUND

The present invention discussed herein generally discloses an isolation system for storing and handling work pieces. More particularly, a container that protects the work pieces while being moved around in a processing facility is provided.

Increasing the quality and manufacturing yield for liquid crystal displays (LCD) used in manufacturing flat panel displays (FPD) is a continually challenging process in that improvements are incrementally made. Adding to the challenge is the dramatic increase in panel size as large and widescreen televisions have become more and more popular. In order to obtain the highest quality picture, FPD manufacturers must affordably test all panels while decreasing test time and increasing quality and yield. Yields for large area FPD are not high enough due to damage to the glass panels attributed to particle contamination. The problem has become more acute as panel sizes have increased and pattern dimensions have decreased.

In order to increase the yield and quality of the flat panel displays within the processing facility, the embodiments described herein provide for a wire cassette configured to isolate and protect the enclosed FPD from particulate contamination.

### SUMMARY

Broadly speaking, the present invention fills these needs by providing a method and apparatus for transporting a large area substrate. It should be appreciated that the present invention can be implemented in numerous ways, including as a method, a system, or an apparatus. Several inventive embodiments of the present invention are described below.

In one embodiment, a container for supporting substrates for processing is provided. The container includes a base, a top, and side panels connecting the base and the top. A support structure is disposed in the container. The support structure is configured to support the substrates within the container. The support structure has rows of multiple tensile members extending across a width of the container. Each row of the multiple tensile members is configured to support a substrate, wherein one of the side panels includes a moveable flexible membrane enabling access into the container. A support structure for the flexible membrane includes a synchronization mechanism for synchronizing movement of the flexible membrane with a receiving module of a processing tool.

In another embodiment, a system for transporting substrates is provided. The system includes a container for supporting substrates for processing. The container includes a base, a top, and side panels connecting the base and the top. The container further includes a support structure disposed in the container. The support structure is configured to support the substrates within the container. The support structure has rows of multiple tensile members extending across a width of the container. Each row of the multiple tensile members is configured to support a substrate, wherein one of the side panels includes a moveable flexible membrane enabling access into the container. The system includes a substrate transfer station configured to access the substrates through the access enabled by the flexible membrane.

In another embodiment, a container for supporting semiconductor processing substrates is provided. The container includes a base, a top, and side panels connecting the base and the top. A support structure is disposed in the container. The support structure is configured to support the substrates within the container. The support structure has an array, arranged in rows and columns, of multiple tensile members extending across a width of the container. Each row of the multiple tensile members is configured to support a substrate, wherein one of the side panels includes a moveable flexible membrane enabling access into the container. The container includes a rotating member extending across an edge of the one of the side panels, the rotating member guiding the flexible membrane during movement.

Other aspects and advantages of the invention will become apparent from the following detailed description, taken in conjunction with the accompanying drawings, illustrating by way of example the principles of the invention.

### BRIEF DESCRIPTION OF THE DRAWINGS

Aspects of the present invention will become apparent from the following detailed description, taken in conjunction with the accompanying drawings, illustrating by way of example the principles of the invention.

FIG. 1 is a simplified schematic diagram illustrating a high level view of an exemplary layout for a flat panel display manufacturer in accordance with one embodiment of the invention.

FIG. 2 is a simplified schematic diagram illustrating a perspective view of the manufacturing environment in which the containers described herein may be utilized in accordance with one embodiment of the invention.

FIG. 3 is a simplified schematic diagram illustrating a container having an outer shell in accordance with one embodiment of the invention.

FIG. 4 is a simplified schematic diagram illustrating the container of FIG. 3 with the cover removed in accordance with one embodiment of the invention.

FIG. 5 is a back view of the uncovered container of FIG. 4 in accordance with one embodiment of the invention.

FIG. 6 is a simplified schematic diagram illustrating a cassette isolation station, also referred to as a tool mini-environment, in accordance with one embodiment of the invention.

FIG. 7 illustrates a simplified schematic diagram of the container positioned in front of the cassette station in accordance with one embodiment of the invention.

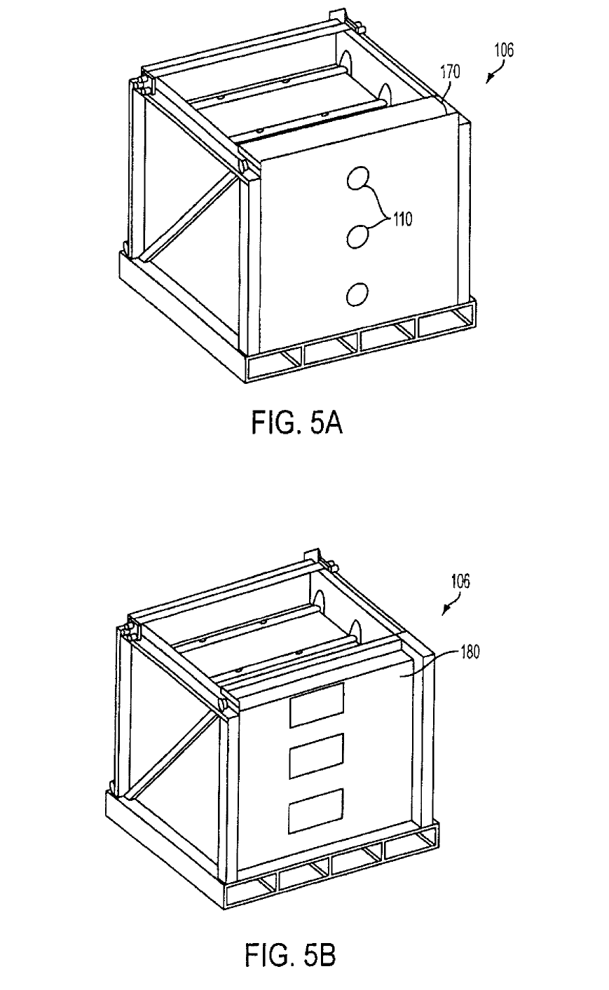

FIGS. 5A through 8F illustrate the docking and opening of the synchronized doors between the cassette station and the container in accordance with one embodiment of the invention.

FIGS. 9A through 9C illustrate a simplified schematic diagram of alternative embodiments for the container in accordance with one embodiment of the invention.

FIG. 10 illustrates a container in which a single membrane door is provided and a panel transfer end effector enters from the bottom of the container.

FIG. 11 illustrates a container having a single membrane door that opens in the front of the container and a panel transfer paddle is internal to the container.

FIG. 12 is a simplified schematic diagram illustrating a single membrane door for a container in which a panel transfer paddle is contained inside the container while the container is raised vertically through external means in accordance with one embodiment of the invention.

FIG. 13A illustrates a container having a single membrane door and a panel transfer paddle that is contained within the container.

FIG. 13B is an alternative embodiment to the embodiment of FIG. 13A where the lift spools are independent.

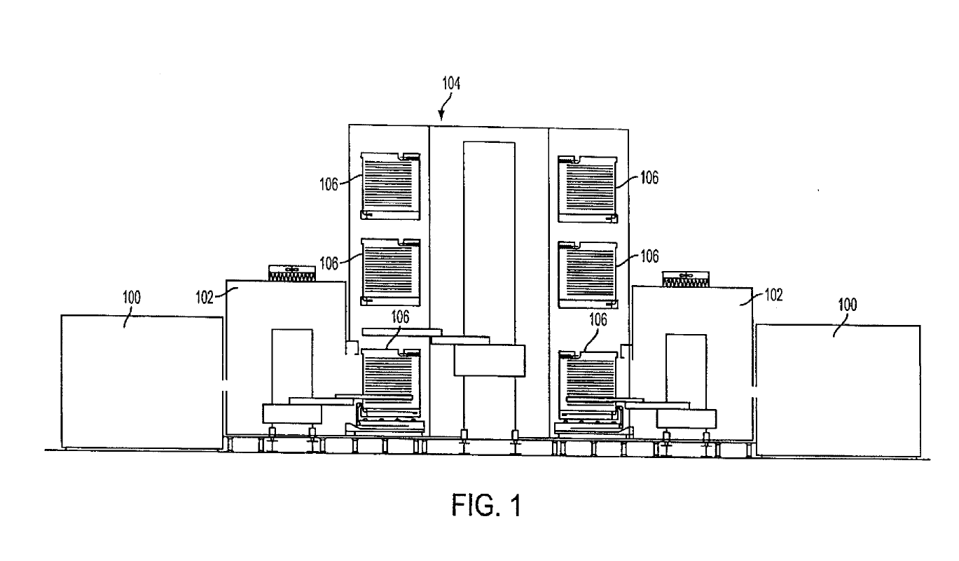

FIGS. 13C-1 and 13C-2 are simplified schematic diagrams illustrating a support frame for a wire cassette and a paddle transfer unit in accordance with one embodiment of the invention.

FIG. 14 is a simplified schematic diagram illustrating the container having a slot in the membrane door in which a panel is moved out from the container.

FIGS. 15A and 15B illustrate a container having a single membrane door and panel lift and transfer posts that enter the container from a bottom of the container.

FIGS. 16A through 16D illustrate various perspective views of the container with a door slit in accordance with one embodiment of the invention.

FIGS. 17A-17C are simplified schematic diagrams illustrating cross sectional views of the container and support device for an external transfer mechanism in accordance with one embodiment of the invention.

FIG. 18 illustrates a substrate container, a tool loading mini-environment, and a processing tool (e.g., manufacturing tool, measurement tool, etc.) in accordance with one embodiment of the invention.

FIG. 19 is a perspective view illustrating one embodiment of a container.

FIGS. 20 and 21 illustrate a container having a slotted door in accordance with one embodiment of the invention.

FIGS. 22A and 22B illustrate one embodiment of a flexible door that could be pulled towards the container frame at the end of closure to minimize sealing gaps in accordance with one embodiment of the invention.

FIG. 23 is a simplified schematic diagram illustrating a container with a flexible membrane door in another embodiment.

FIGS. 24A and 24B illustrate that the vertical assembly adjusts to align vertically with a substrate stored in the container in accordance with one embodiment of the invention.

FIGS. 25A-25B illustrate another embodiment of a substrate transfer system.

### DETAILED DESCRIPTION

An invention is described for a container and a system for transporting and/or storing flat panel displays (FPD) whether or not involved in semiconductor manufacturing operations. It will be obvious, however, to one skilled in the art, that the present invention may be practiced without some or all of these specific details. In other instances, well known process operations have not been described in detail in order not to unnecessarily obscure the present invention.

The embodiments described herein provide for a system that provides environmental isolation for large area substrates, such as flat panel displays, solar cells, etc. In one embodiment, a container, also referred to as a wire cassette, with or without a blower providing filtered air inside of the cavity, defined within the container is provided. The container includes tensile members horizontally disposed within the container that provide support for a number of large area substrates. Each support row within the container includes a plurality of tensile members and the container includes a plurality of support rows. The tensile members may be coated or uncoated wire in one embodiment, or may be r tape supports or bands. The tensile members provide support for a large area substrate and are composed of a material that will not shed particles and is compatible, e.g., will not react or cause damage to the substrates being supported. The containers may be equipped with a membrane door (also referred to as a flexible door) that opens to allow access to one or more sides of the container. The flexible door may provide access by opening up for one or more sides of the container in one embodiment. Alternatively, a slot in the membrane door may index to a plane for each support row allowing for extraction of the large area substrates. The flexible door may open a front to the container or a front and/or a bottom of the container. Thus, the flexible door may be a single piece or two separate pieces that open in opposite directions. The drives for opening the flexible door may be integrated into the container or external to the container, as outlined in Table 3. The flexible door may be composed of any suitable low shedding material capable of withstanding the opening and closing functionality and that can bend. Some exemplary compounds include polyester films, e.g., MYLAR™, thin metal foil, e.g., stainless steel foil, woven compounds, e.g., KEVLAR™, etc. It should be appreciated that the flexible membrane need not be composed of a uniform material. For example, multiple components may be combined to define the flexible door.

A transfer mechanism that can be either external or internal to the container is included. The transfer mechanism provides access to the substrates or may move the substrates out of the container so that an external device, such as a robot, can capture the substrate for transport to another destination. The internal transfer mechanism is integrated into each container, while the external transfer mechanism is provided for each station where the container is being handled. Exemplary structures to accomplish the functionality of the internal and external transfer mechanisms include belts, air bearings, rollers, etc. which are also outlined in Table 1. The panel handling robot or transfer mechanism that eventually transports the large area substrates from or to the container may reach into the container in conjunction with the transfer mechanism raising the large area substrates from tensile members. In another embodiment, the robot may provide leading edge extraction where an edge of the large area substrate is provided to the robot, e.g., from the mechanism raising the large area substrates. The robot can then latch onto the front edge and pull the entire substrate through leading edge extraction with either a vacuum grip or an edge grip through the assistance of rollers, air bearings, etc. within the cassette. The drive guidance, and synchronization for the internal transfer frame is outlined in Table 3 and illustrated further in the attached Figures. The up and down movement of the large area substrate may be provided through different indexing mechanisms as outlined in Table 4, where either the container can move or is fixed. The following Figures provide exemplary embodiments of the system. In addition, Tables 1-4 provide additional material and details describing different embodiments for the system and the container.

FIG. 1 is a simplified schematic diagram illustrating a high level view of an exemplary layout for a flat panel display manufacturer in accordance with one embodiment of the invention. Stocker 104 includes a plurality of containers 106 that are positioned such that one of containers 106 supplies a corresponding cassette station 102. Stocker 104 will accommodate the movement of containers 106 in order to supply cassette stations 102 with the necessary large area substrate, such as a flat panel display (FPD). Cassette station 102 will retrieve a FPD from a corresponding container 106 in order to deliver the FPD to a corresponding process tool 100. Once the processing has completed, the cassette station, through the robot contained therein, will retrieve the processed substrate and return the processed substrate to the corresponding container 106. Containers 106 are configured to protect and isolate the FPD contained therein. As described in more detail below containers 106 store the FPD substrates in a substantially horizontal orientation.

Container 106 may be a sealable device in which a retractable flexible membrane, which may also be referred to as a container door or shield, is used to close and open to enable access to the FPD contained therein. In one embodiment, the flexible membrane door may be retracted over rollers to allow access to the FPD. In another embodiment, the opening of the retractable flexible membrane for containers 106 is synchronized to the opening of a door for cassette station 102. This synchronization would minimize particulate contamination as the cassette is opened to the clean environment of cassette station 102 and sealed or closed when not in flow communication with the clean environment. It should be appreciated that the configuration of the containers described herein enables the containers to be stacked in a spatially efficient manner. Consequently, the containers may be used for shipping purposes in the instances where the FPD is sent to another facility for additional processing or any other reasons for shipment. In another embodiment, container 106 may include a fan and filter to provide its own internal controlled mini-environment. Containers 106 may use coated wire supports, thin tape type supports, e.g., where the tape strip is a strip of stainless steel with or without a coating, or some other type of band to support the FPD thereon.

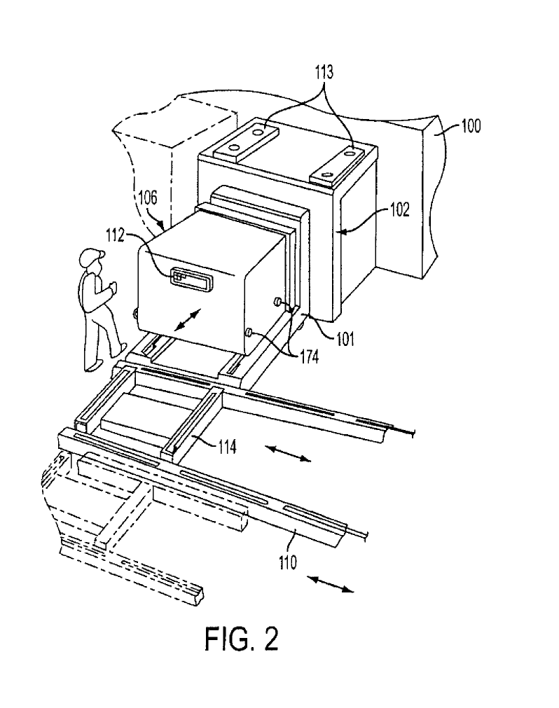

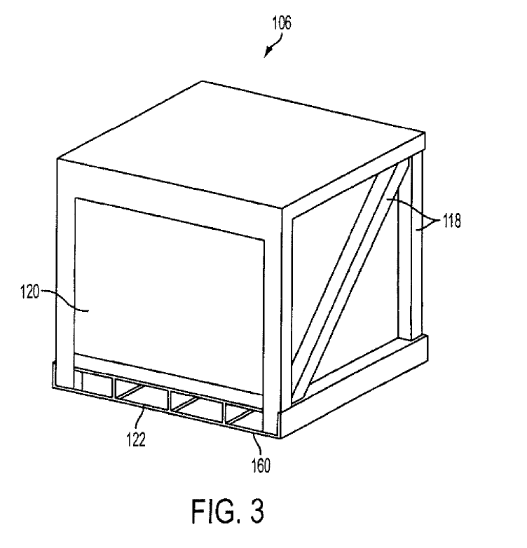

FIG. 2 is a simplified schematic diagram illustrating a perspective view of the manufacturing environment in which the containers described herein may be utilized in accordance with one embodiment of the invention. Container 106 is supported on conveying system 110 which may be comprised of belts, wheels or some other suitable conveying mechanism and positioned into or in front of cassette station 102. Cassette station 102 includes fan/filter units 113 and interfaces with process tool 100. Container 106 may include a fan filter configuration 112 in order to provide a controlled mini-environment within the container. However, it should be appreciated that fan filter 112 configuration is optional. Conveying system 110 includes lifting mechanisms 114 in order to transport container 106 around the manufacturing facility through the different transport zone conveyors. Container 106 includes lift points 174 to assist in the transportation/storage of the containers or in the movement of internal paddles as described in more detail below. It should be appreciated that FIG. 2 is an exemplary figure provided to give guidance as to one exemplary use of the containers. That is, the transport and conveying mechanisms of FIG. 2 are not meant to be limiting as alternative transport and conveying mechanisms may be used depending on the application. It should be noted that containers 112 are relatively large due to the large nature of the FPD being processed.

FIG. 3 is a simplified schematic diagram illustrating a container having an outer shell in accordance with one embodiment of the invention. Container 106 includes a cover in which rigid supports 118 provide structural stability in order to offset the tension of the loaded container. That is container 106 is capable of holding the FPD panels resting on tensile member supports within container 106 without deflecting due to the weight of the FPD panels. Container 106 includes flexible membrane door 120 which is capable of opening or closing as described and illustrated further below. Container 106 also includes a base 122 which is configured to accommodate conveyors, automatic guided vehicles, rail guided vehicles, and other docking features.

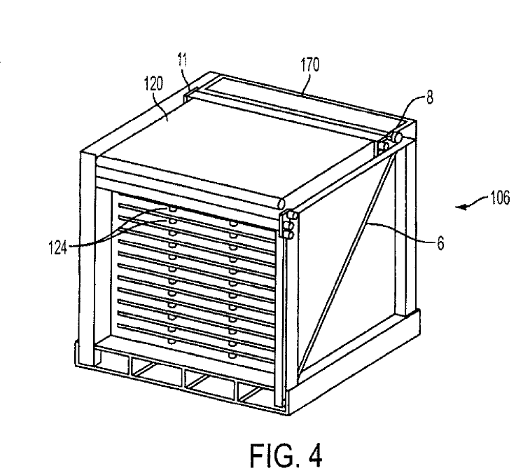

FIG. 4 is a simplified schematic diagram illustrating the container of FIG. 3 with the cover removed/retracted in accordance with one embodiment of the invention. Container 106 includes a number of panel supports 124, e.g., cantilevered support members, which provide support for FPD panels contained therein. Membrane door 120 is illustrated in an open position wherein door drive guide rollers and a belt synchronization mechanism are used to open the membrane door. The belt synchronization mechanism includes belt 6, which is guided or driven by pulley 8. It should be appreciate that on an opposing side, another belt/pulley combination exist. In one embodiment, an air inlet plenum 170 is included within container 106 to distribute clean air forced into the container.

FIGS. 5A and 5B are back perspective views of the uncovered container of FIG. 4 in accordance with one embodiment of the invention. FIGS. 5A-5B illustrate that the container may include a clean air-flow system. In this embodiment, container 106 includes an air inlet plenum 170, air outlet plenums and multiple clean air blowers 110. The blowers 110 pull outside air into the container to create a flow of clean air within the container. FIG. 5B illustrates that a diffuser screen 180 may be placed between the plenum and the blowers. The blowers 110 create clean airflow into the container. It should be noted that this creates a slightly higher pressure of clean air in the container. The air will flow out of the proximity seal formed by the container door and other vents may be designed to sweep particles away from contaminating surfaces such as rollers and bearings. The space between the blower panel and the diffuser screens 180 is the plenum, which allows the pressure to be more evenly distributed before the air exits the plenum and enters the container. In other words, the “plenum outlet” is the outlet feeding the interior of the container. If space was allocated for a plenum the filter elements may be arranged differently as they would be in a mini-environment, i.e., the blowers would pressurize the plenum volume and the filters would be in the place shown as the diffuser screens. In this embodiment, the filters would benefit from the even pressure of the plenum and provide non-turbulent airflow. It is possible that filters could be directly attached to the blowers, producing a flow of air that is clean but may be somewhat turbulent to save the space and still provide a clean pressurized interior for the container.

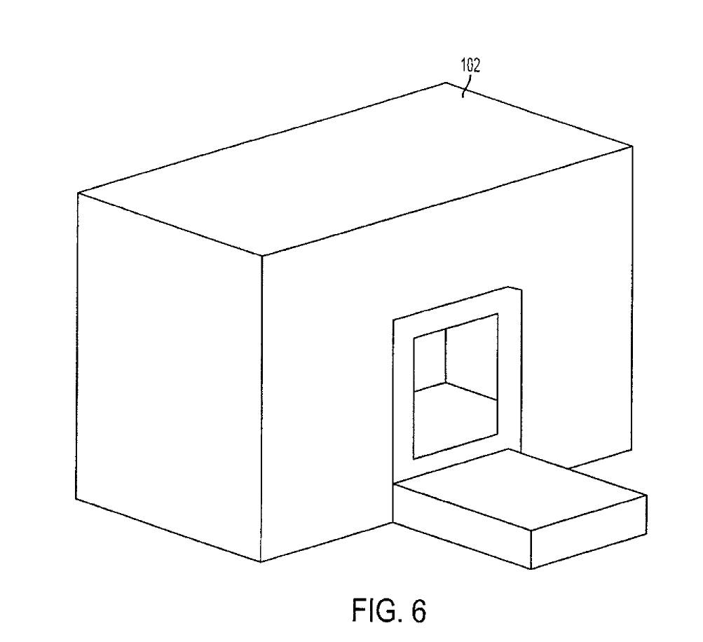

FIG. 6 is a simplified schematic diagram illustrating a cassette isolation station, also referred to as a tool mini-environment, in accordance with one embodiment of the invention. Tool mini-environment 102 includes a load port flexible membrane door which may be synchronized with the membrane door of the container when the container is positioned against the load port of the tool mini-environment on the container handling rollers. In another embodiment, a transfer mechanism is disposed below the load port and either the container or the transfer mechanism may move or index to assist in the movement of the FPD into and/or out of the container.

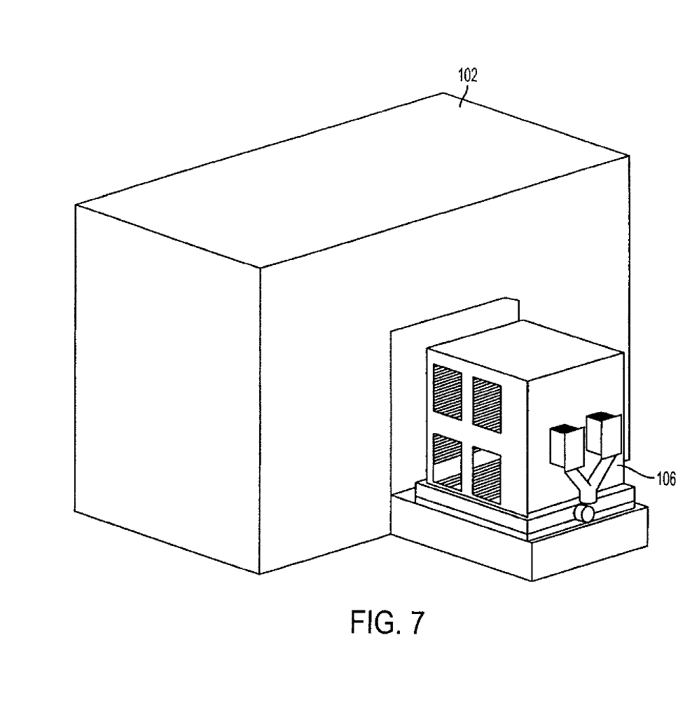

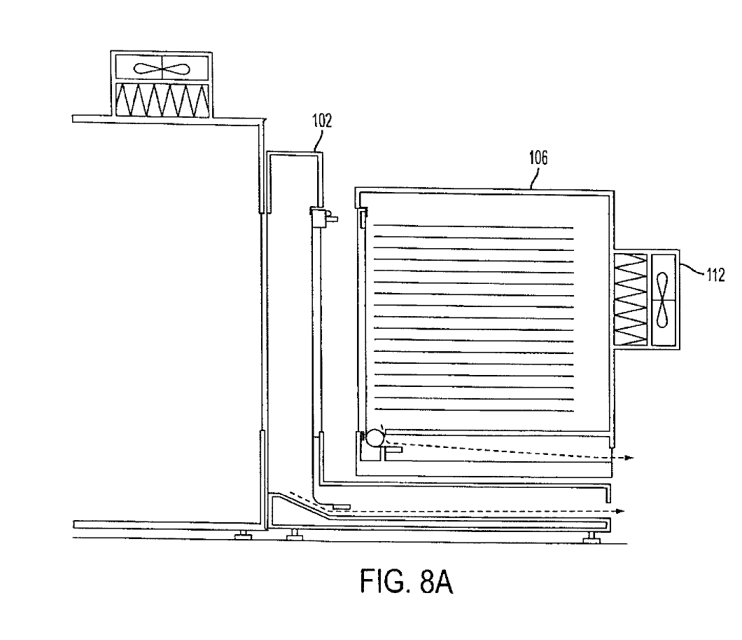

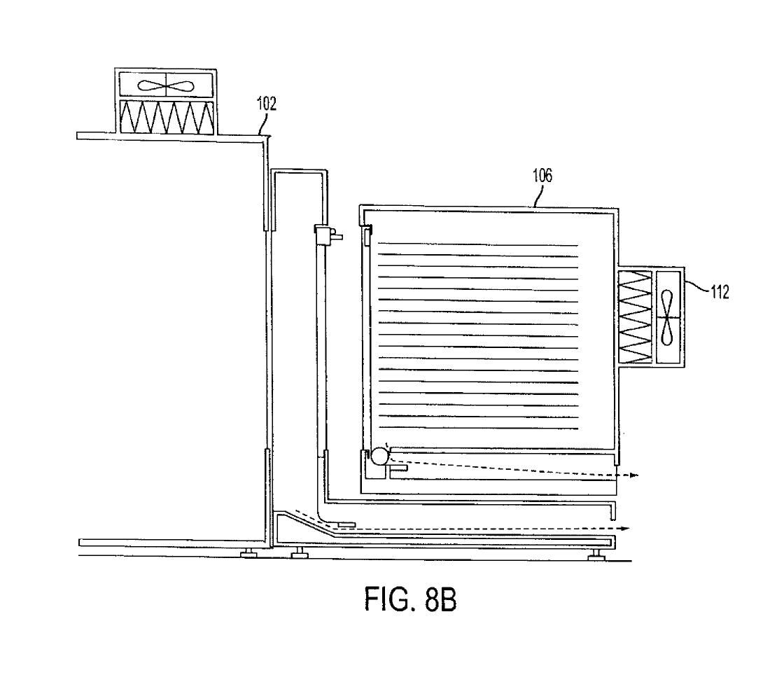

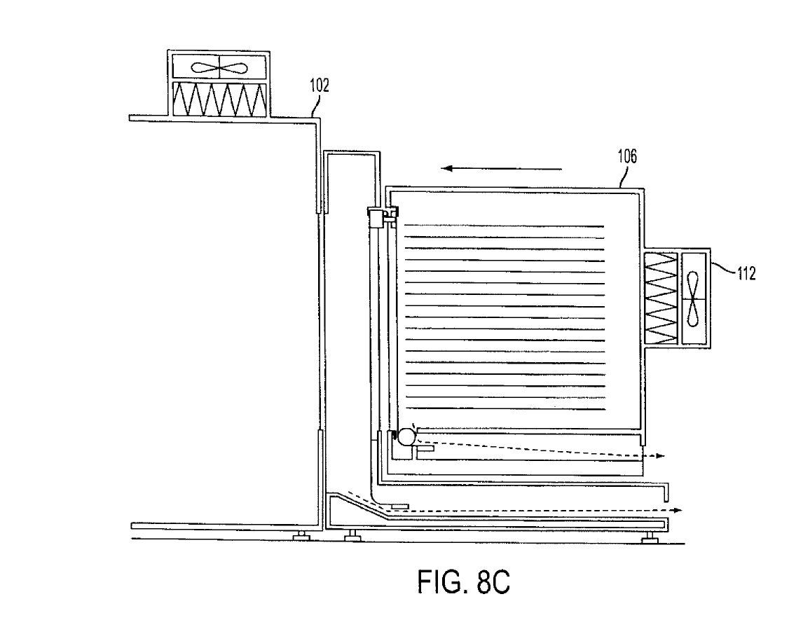

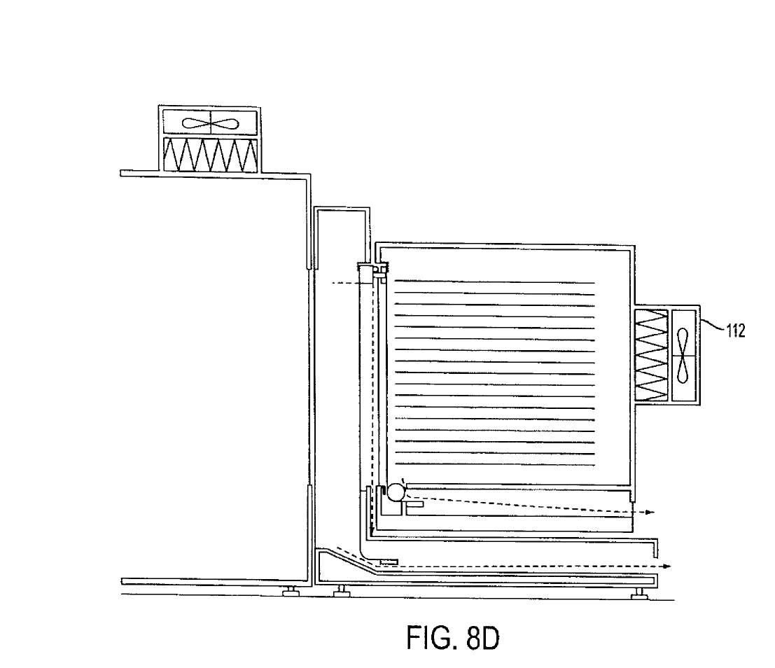

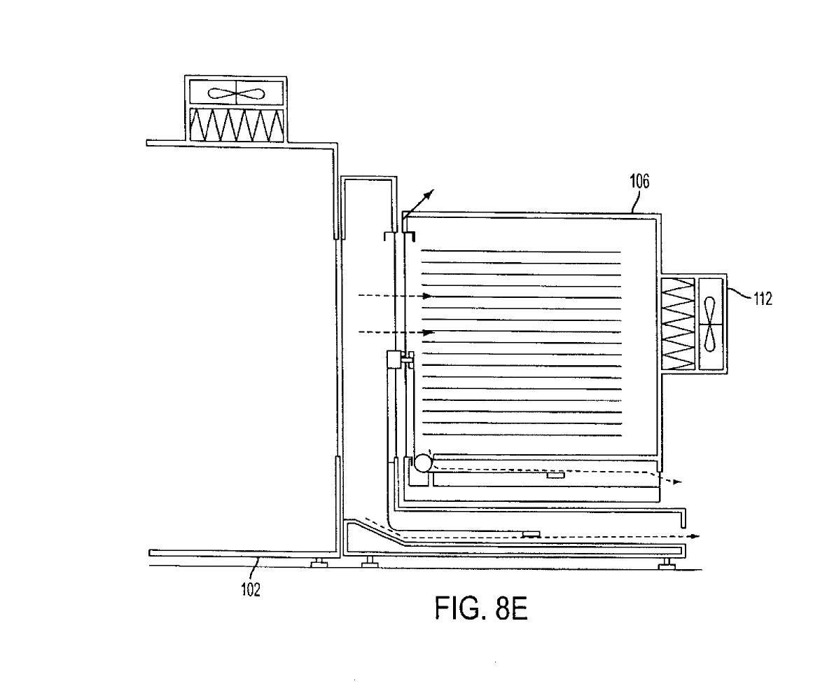

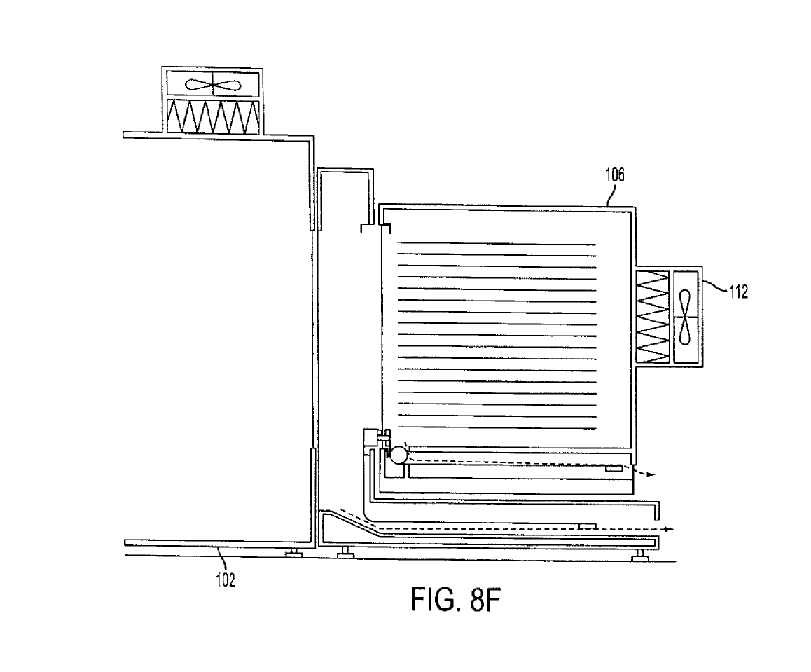

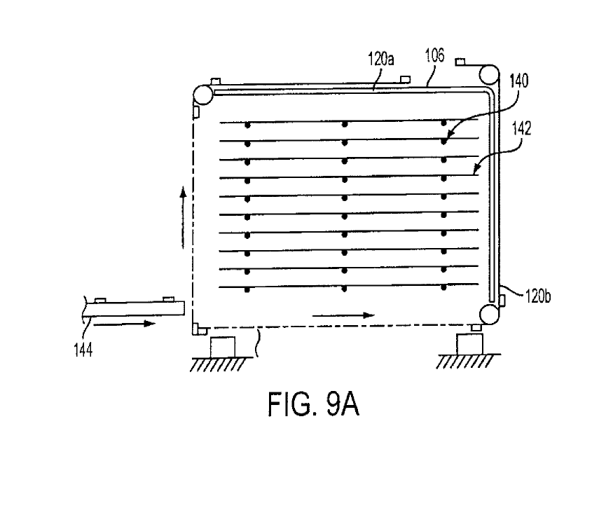

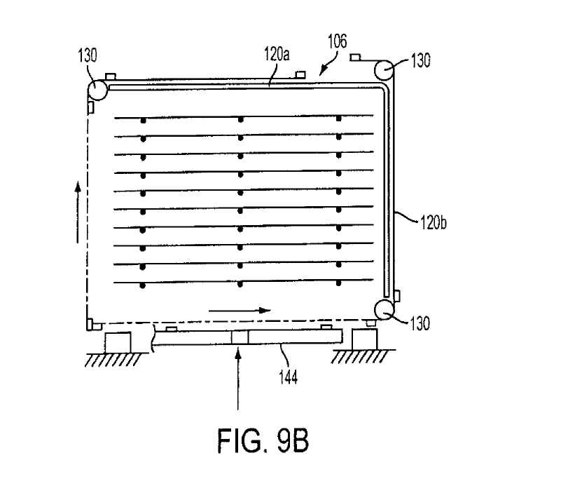

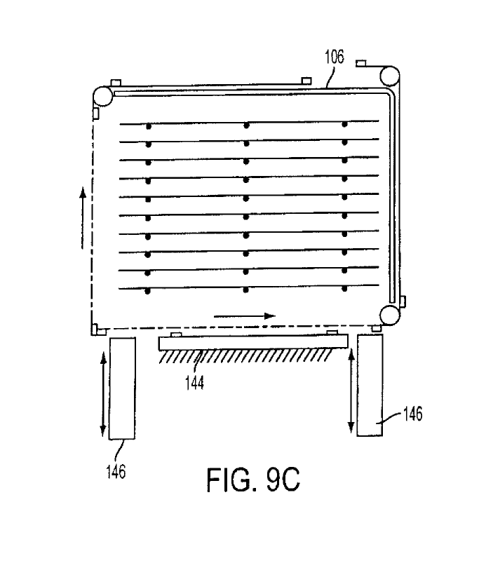

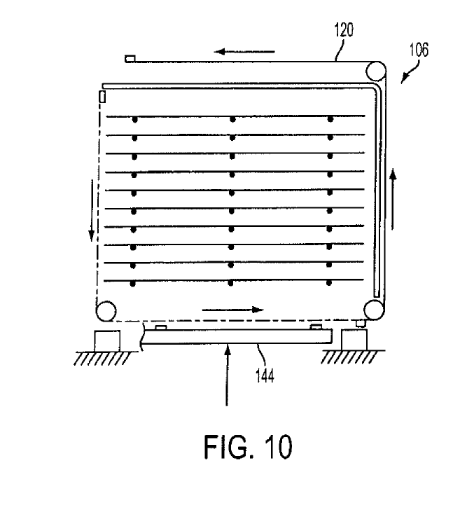

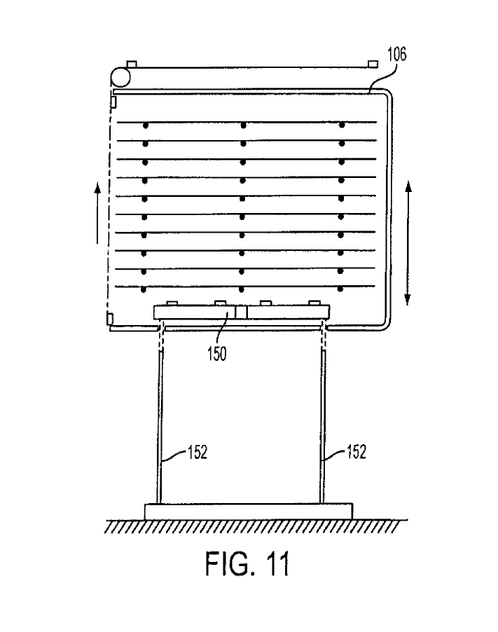

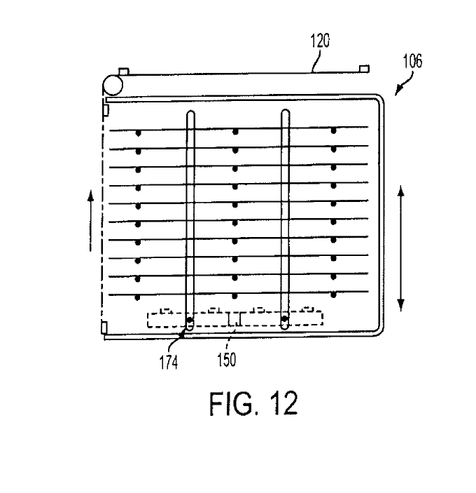

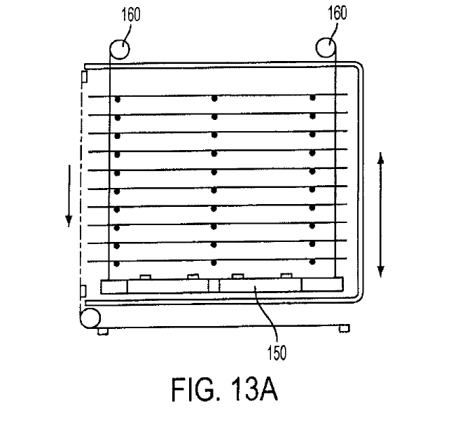

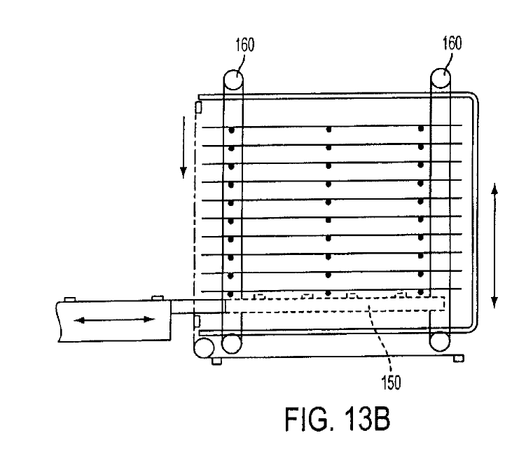

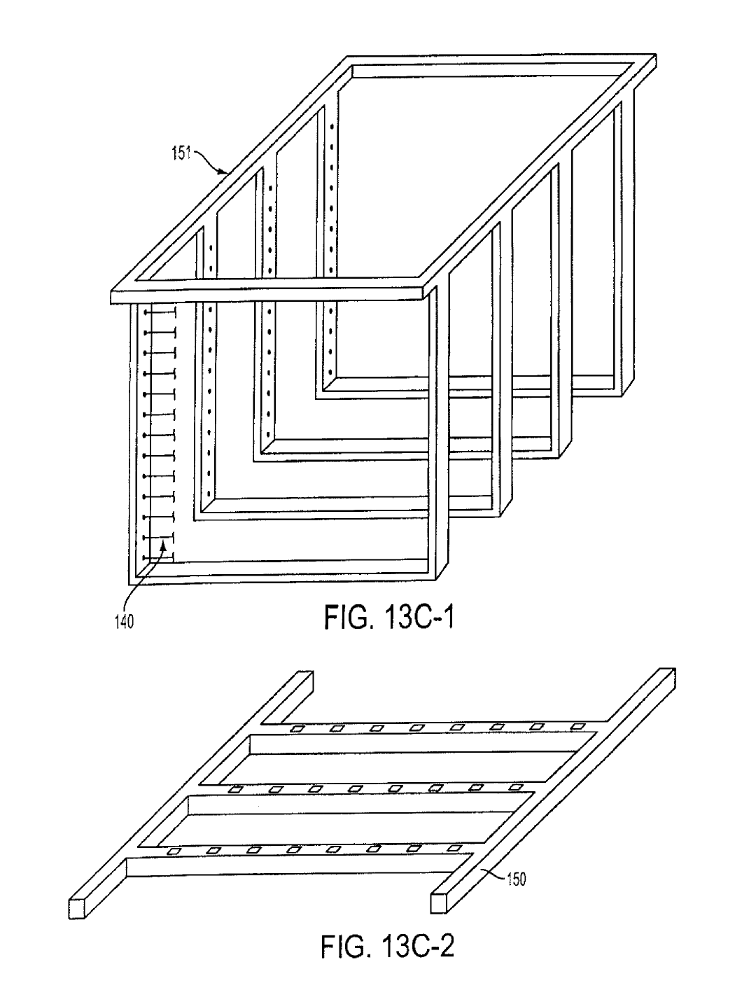

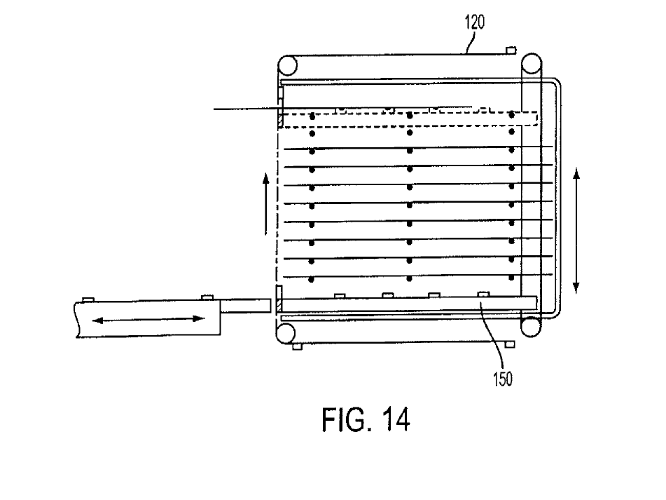

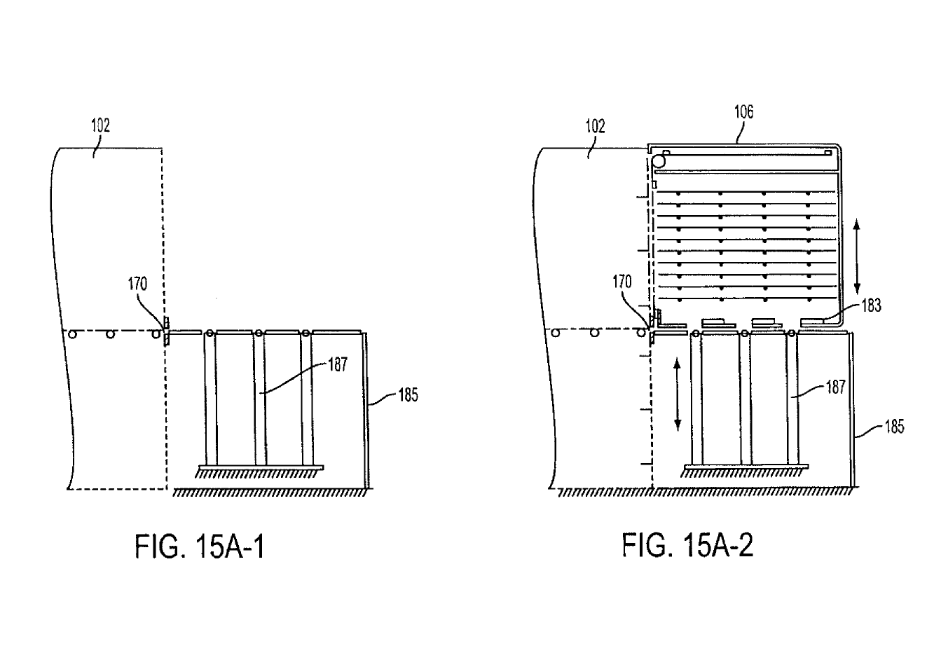

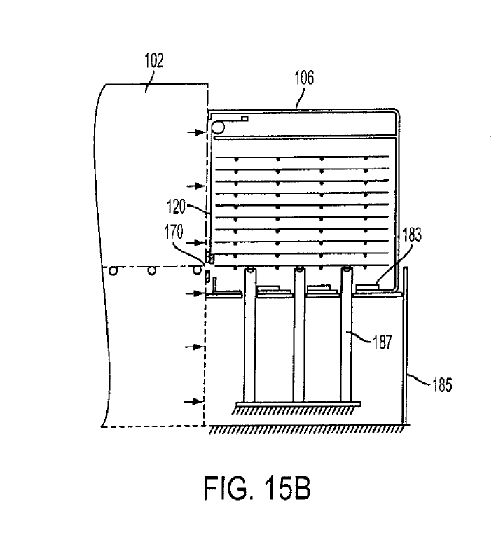

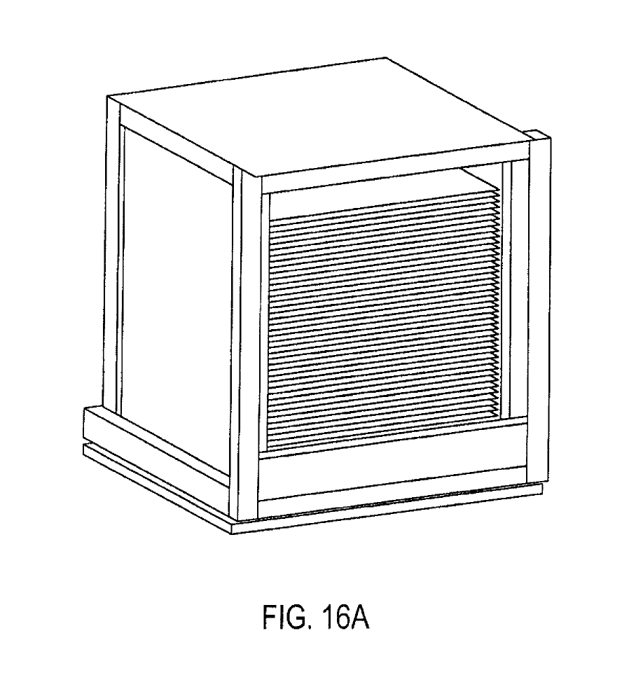

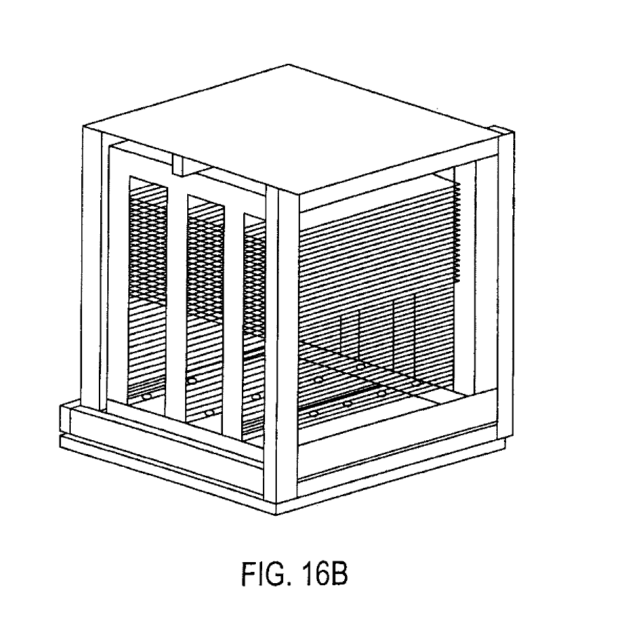

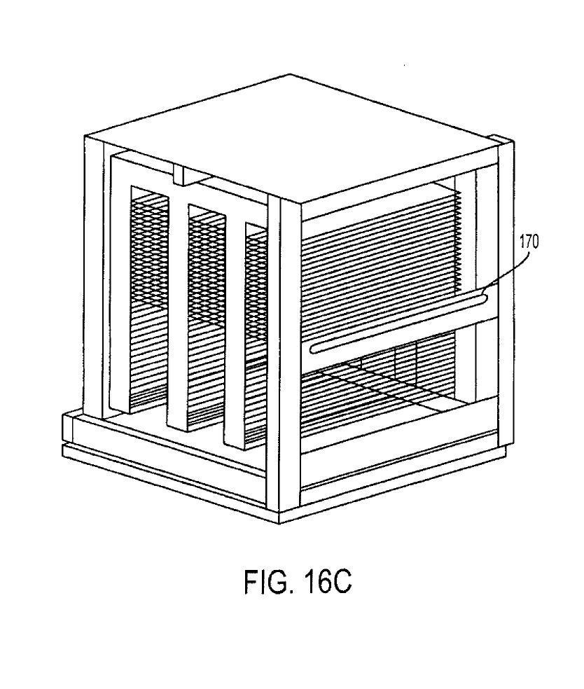

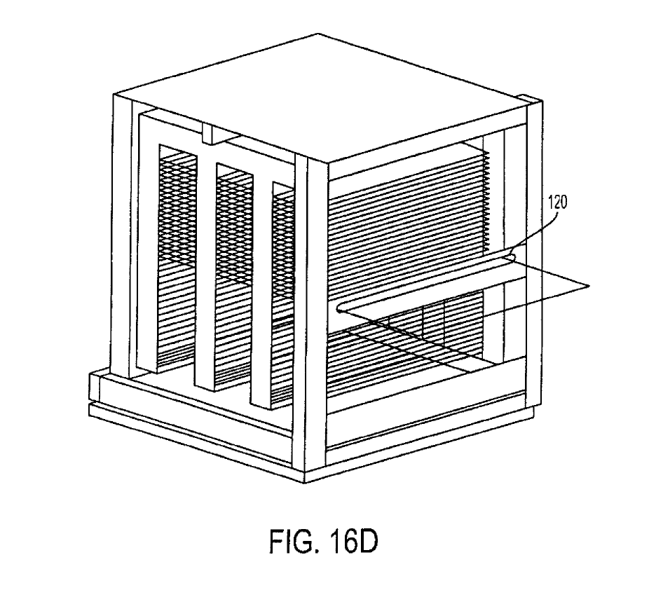

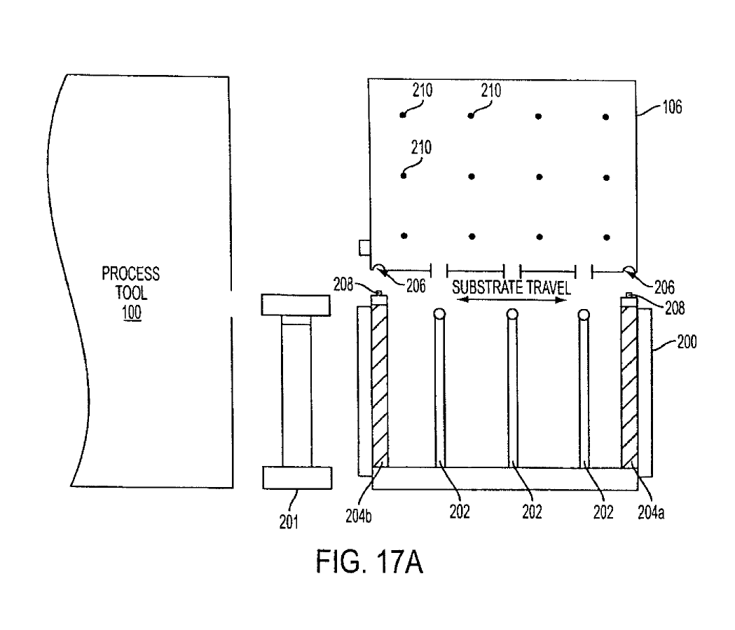

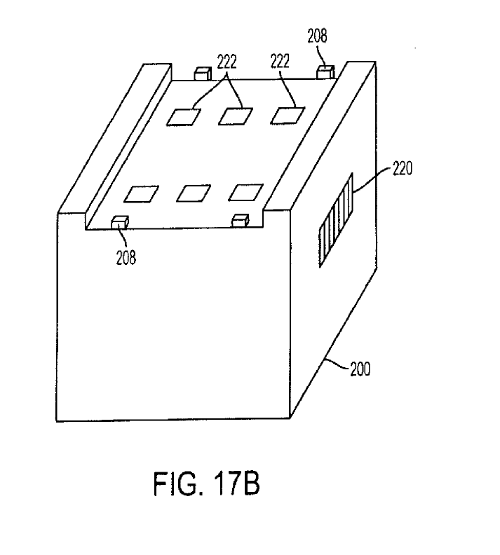

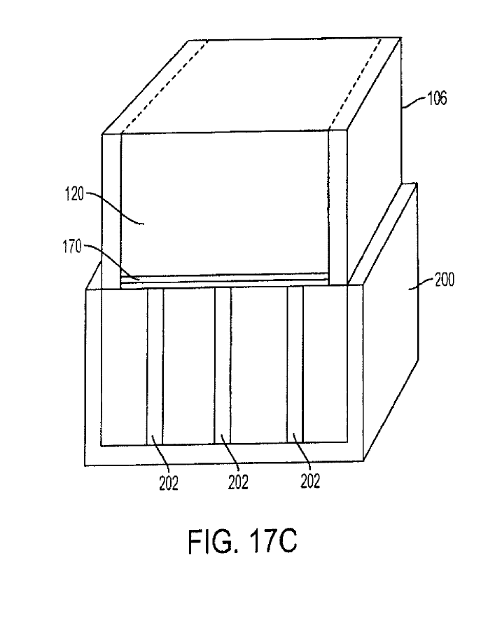

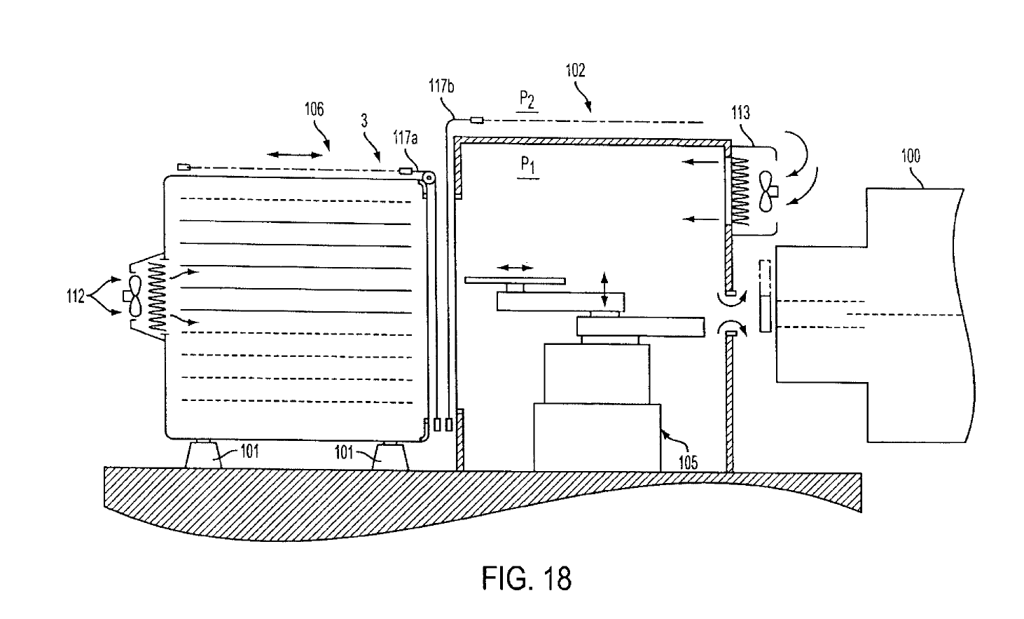

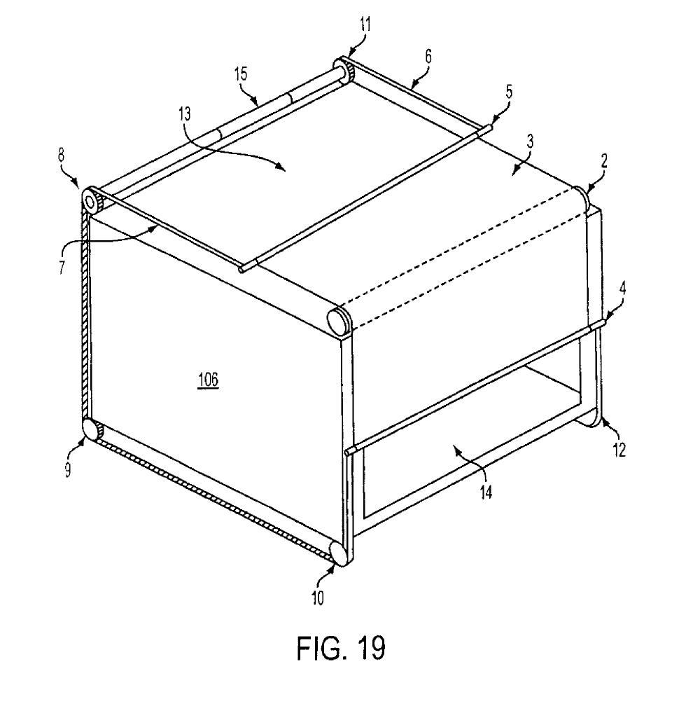

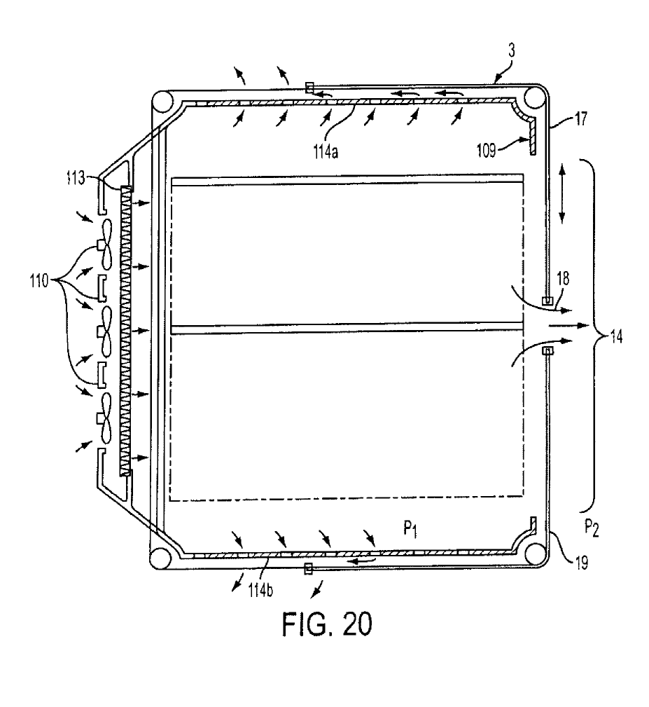

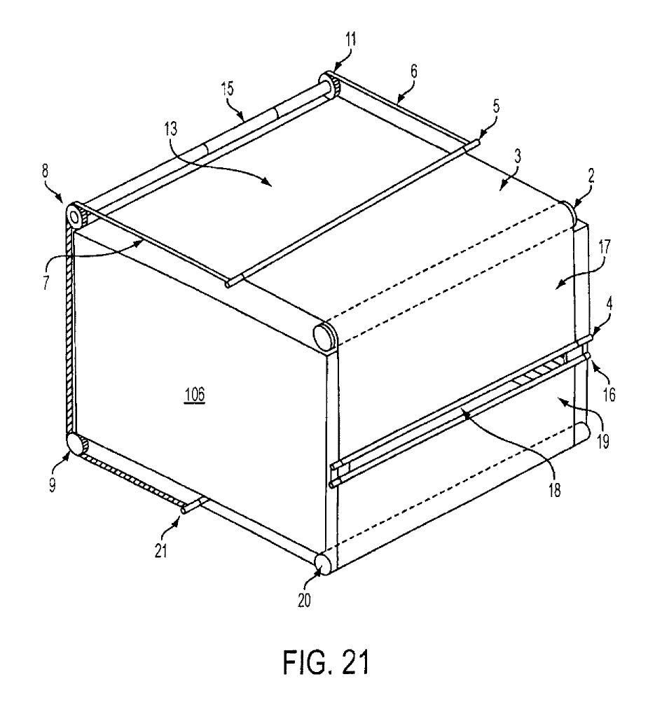

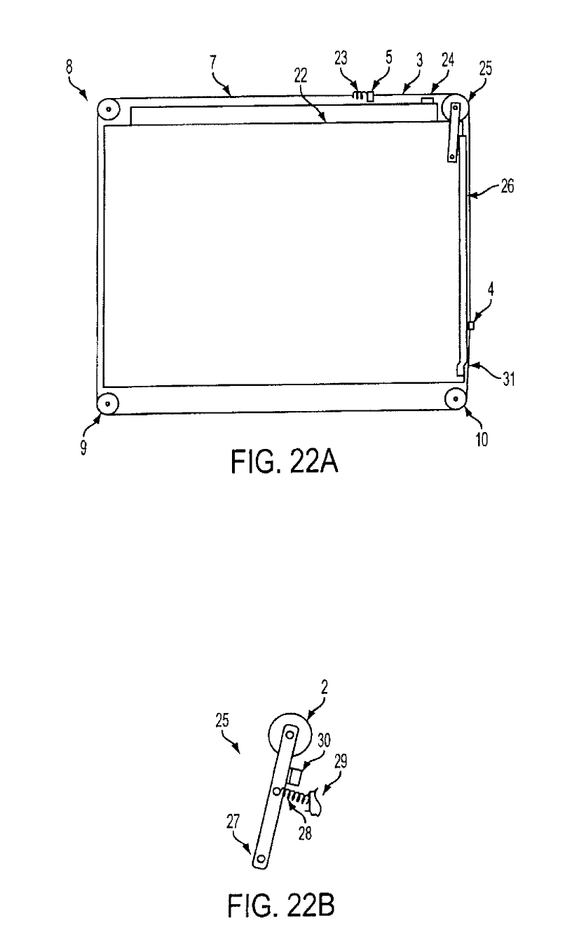

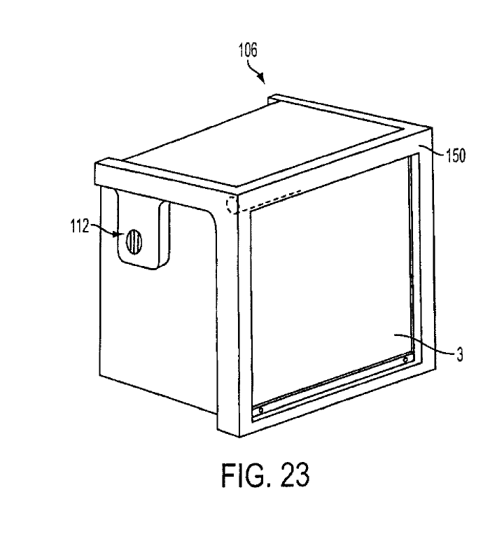

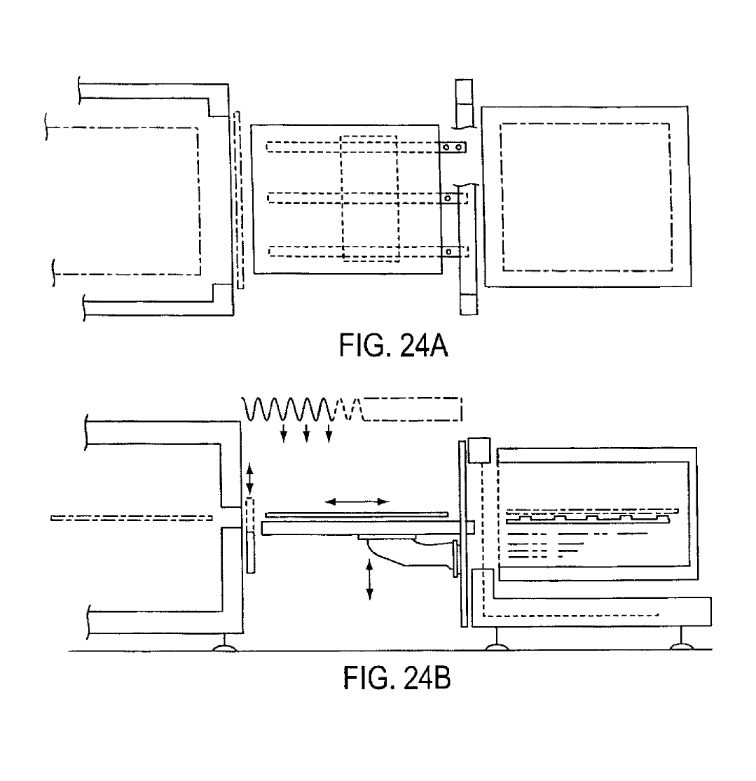

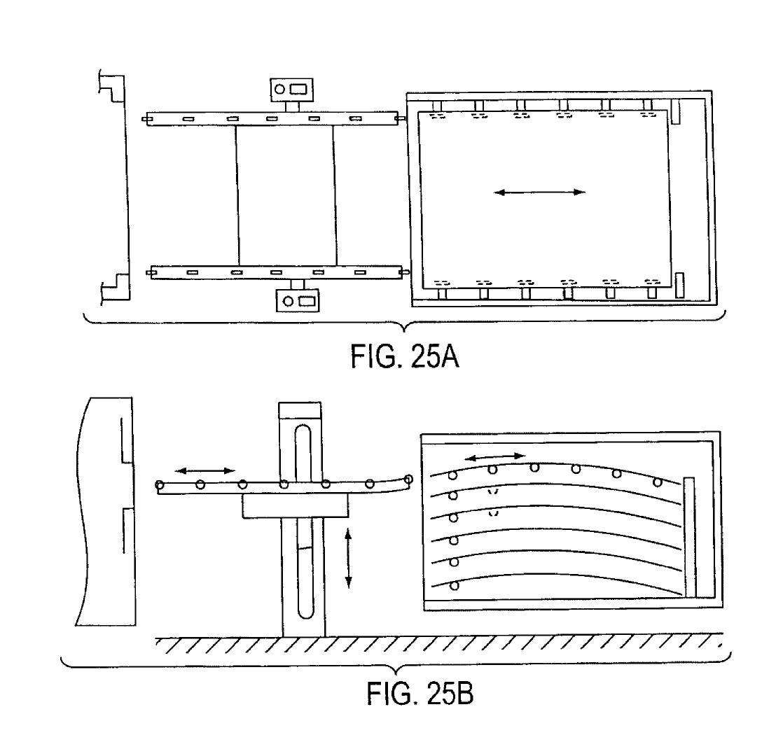

FIG. 7 illustrates a simplified schematic diagram of the container positioned in front of the cassette station in accordance with one embodiment of the invention. Container 106 rests on a platform, which may be referred to as a load port, in front of cassette station 102. It should be appreciated that the container may be kinematically placed on the load port to ensure stability and accurate placement in one embodiment. In this position, the doors for container 106 and cassette station 102 are synchronized to drop down to enable access to the FPD panels within container 106. The doors will also close together in this embodiment. Container 106 includes blowers and fan filtration system attached to a backside of container 106, which is optional. For example, if container 106 has the sealable membrane door, exposure to the clean environment of cassette station 102, and the subsequent sealing of the flexible membrane door of container 106, upon completion of the processing ensures that the clean environment is maintained for a relatively long period of time as long as the flexible membrane door of container 106 remains closed. As discussed in more detail below, with reference to FIGS. 9A-15B, as well as TABLES 1-4, different mechanisms for transporting the large area substrates into and out of container 106 are possible.

FIGS. 8A through 8F illustrate the docking and opening of the synchronized doors between the cassette station and the container in accordance with one embodiment of the invention. In FIG. 8A, container 106 is being positioned to dock with cassette station 102. In one embodiment, a pin or some other mechanism may be used so that the doors between cassette station 102 and container 106 are synchronized when the pin is engaged with container 106. In this embodiment, container 106 includes an optional fan filtration unit (FFU) 112. As illustrated in FIG. 8B, container 106 provides for exhaust through door edges, while the load port of cassette station 102 exhausts also through door edges below the docking station. As illustrated in FIGS. 5C and 8D, when container 106 is engaged with cassette station 102 the less clean air contained between the outer surfaces of the opposing doors may be purged through air flow provided between the two opposing doors. Alternatively, vacuum may be applied to purge this area. In FIGS. 8E and 8F, the doors for both cassette station 102 and container 106 are opened and the clean air from cassette station 102 will flow into container 106. It should be noted that the air flow exhaust also sweeps over the corresponding container door and cassette station door when the doors are in an open position. That is, the doors are maintained in a clean environment when in the open position to minimize sources of contamination. It should be noted that a mini environment (ME), as referred to herein provides a flow of filtered particle free air or a positive pressure related to adjacent modules. In one embodiment, the pressure in the container is maintained greater than the external environment to prevent particles from entering the container.

FIGS. 9A through 9C illustrate a simplified schematic diagram of alternative embodiments for the container in accordance with one embodiment of the invention. In FIG. 9A, container 106 includes tensile supports 140 which support FPD 142. Membrane doors 120a and 120b are shown in an open position in which access is provided through a bottom and side of container 106. In one embodiment, end effector 144 moves under a front portion of container 106. In this embodiment, end effector 144 is located at each cassette station. End effector 144 may support and/or move the FPD by belts, rollers, air bearings, etc. That is, the robot, of which end effector 144 is part of, may include a panel paddle transfer extension that extends from the robot and a set of rollers on the robot. The panel paddle transfer extension extends into the container to access the FPD and assist in moving the FPD onto the rollers of the robot, which are external to the container. In one embodiment, the panel paddle transfer extension may include a separate Z drive from the rollers.

Tensile members 140 of FIGS. 9A-9C, which may be referred to as wire supports, bands or tape strips, and are not necessarily composed of wire as mentioned above. As previously mentioned, stainless steel tape/bands may be used in place of wire. Alternatively, nylon, or graphite may compose the tensile members. In one embodiment, where the supports are wire, the wire may be coated with a plastic or some other type of inert material. In essence, tensile members 140 may be any tensile member for supporting an FPD in which the tensile members are compatible with the FPD and will not shed particulates. In one embodiment, the tensile members may have air channels proceeding therethrough in order to provide lift for a FPD disposed above the tensile member so that an end effector or robot may capture the FPD for transport. Of course, the air channels may provide some lateral movement by tilting the FPD for a leading edge to be grabbed by an end effector. Where the air channels are incorporated, the transfer paddle or panel paddle transfer extension may be eliminated. As mentioned above, the air may be selectively applied to multiple rows or a single row of tensile members through a manifold system. The tensile members may be anchored to a side of container 106 in one embodiment. In an alternative embodiment, vertical support members extending from a top and/or bottom surface of container 106 may provide support for the tensile members. In this alternative embodiment, an internal transfer paddle may be accommodated within container 106. Further details on this embodiment are provided with reference to FIGS. 13A-13C.

FIG. 9B illustrates container 106 in which a panel transfer end effector enters from below container 106. Here, panel transfer end effector 144 will enter below container 106 and corresponding load port to provide access to each FPD from the bottom to the top. Panel transfer and end effector 144 is configured to move or index up to each row of FPD's supported by corresponding tensile members. In one embodiment, end effector 144 is configured so that there is a void in a middle section to enable the upward and downward movement of the end effector in container 106. One skilled in the art will appreciate that this can be achieved by having end effector 144 sectioned where a gap exists under a column of tensile members. In another embodiment, where vertical support members inside an inner area of container 106 are used as termination points for the tensile members, a “ladder” structural configuration for end effector 144 enables vertical movement within the container and without interfering with the tensile members. As illustrated in each of FIGS. 9A through 90C, membrane doors 120a and 120b may be supported through rollers 130 and the door stop positions for the open and closed positions are marked accordingly in the Figures. That is, A and B delineate door stop positions with corresponding doors in a closed position, while A′ and B′ delineate door stop positions with corresponding doors in an open position. FIG. 9C illustrates yet another alternative embodiment in which the dual membrane doors move in opposing directions and a panel transfer paddle below container 106 remains stationary. In the embodiment of FIG. 9C, container 106 is raised and lowered through elevator supports 146 while transfer paddle 144 remains stationary.

FIG. 10 illustrates a container in which a single membrane door is provided and a panel transfer end effector enters from the bottom of the container. It should be appreciated that while three tensile members are illustrated in the various Figures discussed herein, this is not meant to be limiting as any suitable number of members may be utilized. In FIG. 10, door 120 wraps around container 106 to enable bottom access for end effector 144. Container 106 rests on supports that are configured to allow the bottom access. In another embodiment, a load port or transfer station may mate with container 106 through kinematic pins for reproducible positioning.

FIG. 11 illustrates a container having a single membrane door that opens in the front of the container and a panel transfer paddle is internal to the container in accordance with one embodiment of the invention. Here, panel transfer paddle 150 is contained within container 106, i.e., is an internal transfer mechanism, and the container can be indexed up or down in one embodiment. In another embodiment, push rods 152 may be raised or lowered with respect to the container in order to provide access to the different FPD contained therein. Thus, either container 106 or push rods 152 may move. It should be appreciated that push rods 152 may be enclosed in a transfer station disposed below a load port supporting container 106, in order to provide a self contained environment for the transfer station.

FIG. 12 is a simplified schematic diagram illustrating a single membrane door for a container in which a panel transfer paddle is contained inside the container and is raised vertically through external means in accordance with one embodiment of the invention. In FIG. 12, container 106 includes panel paddles 150 which are internally contained within the container, i.e., an internal transfer mechanism. Container 106 includes an external lift and guide device to couple with the panel paddles stored in the container to raise and lower panel paddles 150. For example, lift points 174, which are coupled to paddles 150, are provided to couple to an external lift device for movement of the FPD's. It should be appreciated that the membrane door may move in either an up or down direction when opening and closing.

FIG. 13A illustrates a container having a single membrane door and a panel transfer paddle that is contained within the container. In the embodiment of FIG. 13A the lift paddle can be internally guided in the container through lift spools 160 that are synchronized or independent from each other. FIG. 13B is an alternative embodiment to the embodiment of FIG. 13A where the lift spools are independent. It should be appreciated that the embodiment with the internal paddles may utilize the vertical supports that terminate the tensile members so that there is space around the periphery of an internal area of container 106. This space is sufficient to enable room for the lifting bands/belts that drive the internal paddles.

FIGS. 13C-1 and 13C-2 are simplified schematic diagrams illustrating a support frame for a wire cassette and a paddle transfer unit in accordance with one embodiment of the invention. Support frame 151 is illustrated having vertical members that act as termination points for tensile members 140. Panel transfer paddle 150 is configured to move vertically within the container. The horizontal supports having the rollers/transfer mechanism, move in a vertical plane between the vertical members acting as supports/termination points for tensile members 140. In one embodiment, tensile members 140 may have a series of holes that allow air or some other fluid to provide an air bearing when transporting the FPD. It should be noted that a manifold system can be utilized to ensure that one row of tensile members is activated to correspond to the row where the FPD is being transported. As illustrated in FIGS. 13C-1 and 13C-2 the dimension of the

FIG. 14 is a simplified schematic diagram illustrating the container having a slot in the membrane door through which panel access is provided for movement into and out of the container in accordance with one embodiment of the invention. In FIG. 14, an internal transfer mechanism is provided. Here, the FPD is moved out of the container through a slot or slit in panel door 120. In one embodiment, the movement of panel paddle 150 is synchronized with the movement of membrane door 120 to ensure the slot is aligned with the panel being transported.

FIGS. 15A and 15B illustrate a container having a single membrane door and a panel lift and transfer posts that enter the container from a bottom of the container in accordance with one embodiment of the invention. In one embodiment, container 106 is indexed up and down so that each panel may be accessed for transport to cassette station 102. Accordingly, the transfer mechanism in FIG. 15A may be characterized as an external transfer mechanism. In FIG. 15A-1 transfer posts 187 are contained in enclosure 185 to define a self contained environment that may be characterized as a mini-environment that reduces contamination sources. In one embodiment, enclosure 185 may move up and down to access different FPDs within the container of FIG. 15A-2. In another embodiment, transfer posts 187 may move vertically to access the FPDs, while the container is stationary. Slot 170 of cassette station 102, which corresponds to a slot of the flexible membrane door of container 106, is stationary as container 106 moves in one embodiment. In another embodiment, slot 170 is synchronized to move along with transfer posts 187. In order to maintain a high degree of cleanliness, container 106 includes shutters 183 that open and close to allow for access into the container by transfer posts 187 of the transfer station disposed below the container. In one embodiment, shutters 183 are hinged to enable the open and closing and may be activated by an indexer. Shutters 183 may be activated through a key/latch registration mechanism in one embodiment. Here, the insertion of the key triggers the opening of the shutter. Transfer post 187 include rollers mounted on a top surface to lift and transfer in one embodiment. As mentioned above, the transfer posts may alternatively include belts or air bearings. In one embodiment, transfer posts 187 feed the FPD through the slots of the corresponding doors to an edge grip transfer mechanism housed in cassette station 102. This transfer mechanism subsequently delivers the FPD to a process tool, measurement tool, etc.

FIG. 15B illustrates container 106 disposed over a transfer station. Transfer posts 187 are stationary and container 106 is indexed to move vertically through the movement of the top support plate of the transfer station on top of which the container rests. The FPDs are moved through slot 170 to cassette station 102. As mentioned above, the flexible membrane doors of container 106 and cassette station 102 are indexed to align the opening in the doors with the panel being transferred into or out of the container.

FIGS. 16A through 16D illustrate various perspective views of the container with a door slit in accordance with one embodiment of the invention. Door slit/slot 170 is illustrated in FIG. 16C, while FIGS. 16A and 16B illustrate the membrane door in a sealed position. For ease of illustration, the membrane door in FIGS. 16A-D is illustrated as being transparent in order to view the inside of the container. In FIG. 16D a large area substrate is being removed from the container through door slit 170.

FIGS. 17A-17C are simplified schematic diagrams illustrating cross sectional views of the container and support device for an external transfer mechanism in accordance with one embodiment of the invention. Container 106 is configured to be supported by support device 200. In one embodiment, receiving features 206 of container 106 mates with kinematic pins 208 of support device 200. Support device 200 is a self contained device in one embodiment so as to contain and particulate contamination. Lead screws 204a and 204b can provide the mechanism to raise and lower container 106 so that posts 202 may guide a large area substrate into or out of container 106. The large area substrates rest on tensile members 210 within container 106. In one embodiment, each tensile member 210 may include guide means on opposing sides of each tensile member so that the large area substrate stays within an area defined between the guide means. For example, a DELRIN™ ring around each end of each tensile member will achieve this functionality. Wheels or belts disposed on top of posts 202 impart motion to a large area substrate. In one embodiment, transfer robot 201 assists in the transfer of the large area substrate to and from container 106. Transfer robot 201 is optional, as process tool 100 may include a robot or end effector that will extend from the process tool to acquire the large area substrate from container 106 or deliver the large area substrate to the container.

FIG. 17B is a perspective view of support device 200 in accordance with one embodiment of the invention. Support device 200 includes intake filter 220. As support device 200 includes an exterior shroud to define a self contained area, a fan and filtration system may be incorporated into the support device to maintain a clean environment with the self contained area. Apertures 222 are defined on an upper surface of support device 200. Apertures 222 allow for access of the posts of FIG. 17A. Kinematic pins 208 provide for the stable engagement of container 106 with support device 200.

FIG. 17C is a simplified schematic diagram illustrating a perspective view of the container and support device in accordance with one embodiment of the invention. Container 106 is illustrated with flexible door 120. Flexible door 120 includes slot 170 through which large area substrates may pass through. As mentioned above, flexible door 120 may be synchronized with the vertical movement of container 106 over support device 200 so that the slot adjusts to the correct height for the removal or receipt of a large area substrate. The front of support device 200 is illustrated without the shroud so that posts 202 are visible. As container 106 is vertically adjusted over support device 200, posts 200 will engage large area substrates stored within container 106. It should be appreciated that FIG. 17A-C represent one embodiment of the system and that numerous combinations are possible from the various components mentioned herein. It should be appreciated that posts 202 can be configured as a row in between tensile members to accommodate a number of wheels or a larger belt portion on the top portion of each post. In addition, apertures 222 may each be associated with a cover or shutter to close the apertures when the container is removed. In addition, the container may include container shuttle valves as illustrated in FIG. 15A to allow access of the posts into the container. It should be noted that any of the embodiments described herein where an opening into the container is provided, a mechanism for closing the opening when not in use is provided, such as the shutter valves mentioned above.

Moreover, FIGS. 9A through 17C provide numerous alternatives for the various mechanisms described therein. In one embodiment, the panel horizontal transfer mechanism may be provided through internal transfer means, external transfer means, or panel handling robot means. A summary of the different structures used to provide the horizontal transfer mechanism is provided in Table 1. The internal transfer frame drive/guidance means and the corresponding structure to accommodate the internal transfer drive is summarized in Table 2. The container door opening/drive means and the structure for achieving that door opening is provided in Table 3. Container panel indexing means and the corresponding different structures for achieving that indexing is provided in Table 4.

FIG. 18 illustrates a substrate container, a tool loading mini-environment, and a processing tool (e.g., manufacturing tool, measurement tool, etc.) in accordance with one embodiment of the invention. Container 106, as shown in FIG. 18, stores large area substrates in a substantially horizontal orientation within the container. It should be appreciated that the term “large area substrates,” as used herein may refer to any type of substrate, wafer, or workpiece having a diameter of 300 millimeters or more if round. Also, the substrates need not be round as some substrates, such as flat panel displays or solar panels may be a quadrilateral. Thus a large area substrate that is not round refers to a quadrilateral that has a width or a length that is greater than 300 millimeters in another embodiment. In FIG. 18, the container is located in a load position in front of mini-environment 102. Container 106, in this embodiment, includes a closed enclosure except for the front opening, which is sealed with a retractable flexible membrane (also referred to herein as a container door or shield). By way of example only, the flexible membrane may be retracted over rollers to allow access to the substrates. Other devices for retracting the membrane are within the scope of the present invention. It is possible that the membrane will not be in physical contact with the periphery of the front opening at all places, having a small gap that allows the membrane to be retracted without abrasion (minimizing or eliminating this gap will be explained in more detail hereinafter).

The container support mechanism 101 that container 106 is seated on may include a mechanism that moves the front face of the container to the proximity of the front opening of the mini-environment (e.g., similar to a FOUP advance plate of a conventional load port) or the container may be initially loaded on the support mechanism at the position shown in FIG. 18. In this load position, the container door 117a is preferably proximate to the front door 117b of the mini-environment to create a proximity seal between the two doors. Either way, once the container is located in this load position, both the container door of the container and the front door of the mini-environment may be opened, allowing the large area substrates to be accessed by the transfer mechanism 105 within the mini-environment. In one embodiment, the motion of both doors is synchronized to open and close together. This synchronized door motion would minimize particulate contamination because it would not allow the exterior, and potentially contaminated, surface of either door to be exposed to the open volume of the container or the mini-environment. It is within the scope and spirit of the present invention for the process tool to not include a mini-environment 102. In this case, the container front door (or membrane or shield) would be placed proximate to the panel handling system door or access zone of the process tool 100.

The front door of the mini-environment may also couple with the container door before raising the two doors in unison. Coupling the doors together will “trap” particles located on the exterior surface of both doors between the container door and the front door, similar to a conventional port door coupling with a FOUP door. The front door may couple with the container door at any elevation. It is preferable, however, that the front door and container door couple together near the bottom portion of each door. The container door must be able to be raised to a position whereby the workpiece stored in a top shelf of the container is accessible by the substrate handling robot.

When the container door and mini-environment doors are both open, there may be a small gap between them that is exposed to the outside environment. To prevent contaminants from the outside environment from entering the container or mini-environment, the mini-environment 102 may include a fan and filter 113 that provides clean air to the inside of the mini-environment, creating an internal pressure within the mini-environment that is slightly higher than ambient pressure. This pressure difference would force clean air out of the mini-environment through the gap and prevent contamination from the outside. Alternatively, the mini-environment or tool might not include a fan and filter, and instead rely on a clean air flow provided by the optional fan/filter 112 in the container 106. The door on the mini-environment (or tool if no mini-environment is used) may be a rolling membrane as on the container or alternatively the door may be a more conventional rigid door that slides vertically to open and close. It is also possible that the gap may be sealed after the doors are opened by advancing the container until it seals against the mini-environment.

There are various ways that power or a motive force (e.g., mechanical force) could be provided to the container door mechanism and the optional fan and filter system. By way of example only, power could be supplied to the container by:

a.) A portable energy storage device on the container (e.g., battery, super cap, fuel cell, etc.);

b.) Electrical contacts at the loading station;

c.) Non-contact power that is transmitted by electromagnetic field from stationary conductors at the load station to pick-up coils and circuits on the container;

d.) Pneumatic ports at the loading station that provide pressurized gas; and/or

e.) a mechanical linkage that mates with the container when it is at the loading station.

Power sources b), c), d) or e) may be directly controlled at their source outside of the container to control the container door motion, or for example, the actuations/control of the fan and filter unit, or a control signal could be provided at the load station to control the timing of the container door motion or actuation/control of the fan filter unit. There are a number of ways that the control signal(s) could be communicated to the container including, but not limited to, an optical link light emitting diode (LED) and photosensor or electrical contacts at the load station or radio frequency signals.

FIG. 19 is a perspective view illustrating one embodiment of a container. Container 106 has a front opening 14 through which substrates are passed. A moveable door 3 is made from a flexible material which rolls over roller 2 during opening and closing of the door. The lower and upper ends of the door are terminated with bars 4 and 5 respectively. These bars allow a uniform tension to be maintained across the width of the door. The ends of terminating bars 4 and 5 may be supported by guides or slides (not shown) that keep the bars at a fixed distance from the container body during door motion. Each end of each bar is connected to the end of a timing/synchronizing belt. Belt 7 is attached to bar 5, then rolls over pulleys 8, 9, and 10 before attaching to terminating bar 4. In a similar way, belt 6 is attached to the other end of terminating bar 5 and rolls over 3 pulleys on the other side of the container (including pulleys 11 and 12) and is then connected to the other end of bar 4. Shaft 15 connects pulleys 8 and 11 so that the movement of belts 6 and 7 is synchronized. The other pulleys would freely rotate without cross shafts.

One concern would be the particles that could attach to the inside of the door while the door is open or during the opening motion. These particles may subsequently detach from the inside of the door after the door is closed and contaminate the substrates stored in the container 106. There are several ways in which this potential particle problem could be avoided. If a fan and filter was installed on the container 106, and the upper container surface 13 had perforations or other openings (e.g., slots, micro-pores, etc.), then clean air would flow out of the container through the perforations. This clean air flow would keep particles from depositing on the upper surface of the container where they could be transferred to the inner surface of the door 3 when the door is open. The clean air would also flow over the inner surface of the door when it is open.

Another area of concern is particle generation and transfer at the interface between the flexible door material and the roller. Particle generation could be mitigated by reducing the contact between the roller and the door. The roller may, for example, have narrow ridges down its length or raised bumps to reduce contact area between the roller 2 and the door 3. Alternately, the inside surface of the door could have the ridges or bumps to reduce the contact area.

The container door 3 may be opened and closed by various mechanisms. Lower terminating bar 4 could engage a vertical drive mechanism on the mini-environment or tool. The vertical drive mechanism would raise to open the container door and lower to close the container door without any need for a powered actuator on the container. Alternately, an electric motor may be coupled to the shaft 15, the end of roller 2, or any of the timing belt pulleys. Rotational motion of the motor would rotate the shaft, roller or pulley and move the linked system of timing belts and door. Similarly, a linear actuator (e.g., pneumatic device) could be connected to the door or a belt to provide door motion. Any other mechanism for raising or lowering doors is within the scope of the present invention. The door 3 shown in FIG. 2, moves over a roller 2. It is within the scope of the invention for the container to have a frame including a docking interface that encompasses the roller 2 (as shown in FIG. 23).

FIGS. 20 and 21 illustrate a container having a slotted door in accordance with one embodiment of the invention. Door 3 includes upper door section 17 and lower door section 19, which are respectively terminated at bar 4 and bar 16, defining slot opening 18. Bars 4 and 16 are linked at each end to allow motion to be transmitted to both door sections 17 and 19 with one drive. Lower door section 19 rolls over roller 20 and ends at terminating bar 21. As the timing belts 6 and 7 are moved, slot 18 will move up and down with them, allowing access to a single storage position in the container. It is within the scope of the invention for the slot 18 to be large enough to provide access to more than one substrate stored in the container. The slot could also be formed by an aperture cut into a single piece of flexible material or could be formed by an aperture plate attached to the flexible material.

The slotted door container may have the same features for bar guides, particle reduction, and drive mechanism as the container shown in FIG. 19. The bottom surface may also have clean air flow holes to improve the cleanliness of the lower door segment. A vertical drive mechanism on the mini-environment or tool may engage bars 4 or 16 to move the slot to different positions as the large area substrates or wafers are accessed for processing. FIG. 20 illustrates the container 106 including an optional fan 110 and filter unit 113. The fan and filter unit may provide enough clean airflow to assure that particles from the outside environment would not migrate through the slot 18 into the container. In addition, the container may include a walled area including a portion of the front opening 1 of the container. When the slot 18 is moved to cover the wall 109, the container opening is effectively “closed”, as well as leakage permits. The wall 109 in the container opening may be located at any elevation. FIG. 20 illustrates one embodiment whereby the barrier or wall is located in the top section of the container opening 14. When the container door 3 is raised until the slot 18 is located over the wall, the lower portion 19 of the door covers the entire container opening 14. Alternatively, the top portion 17 of the container door may close off the container when the door is moved down.

The port door of the mini-environment, or processing tool, may also include a movable door with a single slot. In this case, once the container is seated in the loading position, the port door would preferably move in unison with the container door so that the port door is aligned with the slot in the container door. The port door may also include a door similar to a conventional port door in an alternative embodiment.

FIGS. 22A and 22B illustrate one embodiment of a flexible door that could be pulled towards the container frame at the end of closure to minimize sealing gaps in accordance with one embodiment of the invention. In this embodiment, that the container includes a movable roller assembly 25. The roller assembly 25 of FIG. 5B includes a roller 2, a pivot arm, a pivot bearing 27, a roller tension spring 28, a spring attachment feature 29 and stop block 31. The pivot arm 26 is held against the stop block 31 until a force vector that is perpendicular to the long axis of the pivot bar exceeds the spring tension of spring 28. The pivot arm pivots at the pivot bearing 27 and separate from the stop block 31. The tension spring force is preferably greater than the belt tension and any frictional forces resulting from door closure. In one embodiment, closing the container door and sealing the container door against the block 31 are accomplished through a single motion. It is also within the scope of the invention for the roller assembly to include a slide bearing assembly.

The drive system in FIGS. 22A and 22B is similar to the drive in FIG. 19. The drive system has timing belt 7, pulleys, and the door is terminated in upper bar 5 and lower bar 4. This drawing shows slides 22 and 26 which are connected to bars 5 and 4 respectively, and provide sliding support. Belt spring 23 has been added to maintain belt tension within a useful range when the door has moved towards the container front. This motion effectively reduces the belt/door perimeter distance and the spring keeps the belt from becoming slack. When the belt and door are moved in the direction to lower the door, upper bar 5 will strike end block 24 that the slide support for bar 4 enters the recessed slide profile 31. The recessed slide profile is a section of the slide that is slightly angled towards the front of the container so that bar 4 moves along its guide path, that end of the door moves toward the container. While bar 4 is moving through the recessed slide profile, bar 5 is immobile against the end stop, increasing force on the roller until the roller assembly pivots toward the end block. The pivoting of the roller assembly in combination with the motion of bar 4 through the recessed slide profile moves all surfaces of the door (below the roller) towards the container, thus minimizing gaps. There may also be retention mechanism to prevent the bar 4 from moving upward due to the force of the roller tension spring displacement once the door has been completely closed.

The drive belt may be replaced by any similar flexible coupling such as a cable, cord, v-belt, flat belt or band. The moveable roller in FIG. 22B could have a linear, rather than pivoting, motion. The pulleys could be placed in different locations and the belt follows a different path as long as they remain connected to the end of the flexible door. The flexible door material could roll up on a torsionally sprung roller the way that a window shade works in one embodiment.

FIG. 23 is a simplified schematic diagram illustrating a container with a flexible membrane door in another embodiment. Container 1, includes a docking interface 150 that is configured to accept a drive pin in one embodiment. The drive pin may engage with docking interface 150 and latch therewith either by rotating or some other suitable mechanism. Container 1 includes fan filter assembly 110 and membrane door 3. In one embodiment, a key may be used as the drive pin and may be used to lock or unlock the flexible membrane door so that the door may be secured for locking or lowered or raised when unlocked. In one embodiment, the key stays captured with the container, such as a rotating latch with integrated retention means.

FIGS. 24A and 24B illustrates that the assembly includes three supports for supporting the substrate. Of course, the assembly may include any number of supports. FIGS. 24A and 24B illustrate that the vertical assembly adjusts to align vertically with a substrate stored in the container in accordance with one embodiment of the invention. Once the assembly and substrate are aligned, the substrate is removed from the container onto the assembly. There are many ways to remove the substrate from the container such as, but not limited to, supporting the substrate by air bearings and allowing the substrate to “glide” from the container to the assembly, supporting the substrate by rollers and activating the rollers to move the substrate from the container to the assembly or supporting the substrate by belts and activating the belts to move the substrate from the container to the assembly. Using air bearings to support and transfer a substrate may require the container supports to be tilted slightly towards or away from the front of the container so that the substrate may glide out of the container. The assembly may also include a mechanical device (e.g., vacuum cup) for gripping a portion of the substrate and pulling the substrate out of the container on the air bearings.

In operation, once the container door and the load port door are open, the assembly may be aligned with any of the substrates stored in the container. A substrate is then removed from the container onto the assembly. If required, the assembly then aligns the substrate with the process tool opening to allow the substrate to be transferred from the assembly to the tool. Once the substrate has been processed, the substrate is transferred back to the assembly, the assembly aligns itself with an empty shelf in the container, and the substrate is transferred back into the container. FIGS. 19A-19B illustrate that it is may be preferable to provide a clean air flow in this transfer zone between the load port and the processing tool to minimize or eliminate particles from contaminating the substrate. The transfer zone may be enclosed or comprise open space within a controlled environment.

FIGS. 25A-25B illustrate another embodiment of a substrate transfer system. The system includes, among other things, a load port (not shown) and a wafer transfer apparatus. The container shown in FIG. 25B stores the substrates in a non-linear or non-planar configuration. Here, the container stores each substrate in a convex configuration. FIGS. 25A and 25B illustrates that a container may also store a substrate in other non-planar configurations, and each substrate is not required to be stored in the container is the same non-planar configuration. In one embodiment, the deflection of each substrate is between 3-4 inches over the length of the substrate or panel. Of course, other deflections are within the scope of the invention. Storing substrates in a non-linear or non-planar configuration adds rigidity to the substrate. The container supports may comprise, by way of example only, rollers, air bearings, pads or belts. Storing the substrate in a non-planar configuration greatly reduces substrate sag and enables simpler support and handling during transfer. The substrates may be intentionally deformed or deflected about their longitudinal centerline or its horizontal centerline. Deformation at the centerline is exemplary and the substrate or flat panel display may be deflected or deformed along any one line or point or multiple lines or points. The deformation is controllable by the location of the support point locations and other forces inflicted upon the substrate. The other forces include gravity or contact induced forces that induce the formation.

TABLE 1
PANEL HORIZONTAL TRANSFER MEANS

| | | |
|---|---|---|
| 1. Internal Transfer | 2. External Transfer | 3. Panel Handling |
| Frame Means | Frame Means | Robot Means |
| a) Panel Drive Means | a) Panel Drive Means | a) Reach In With |

| | | |
|---|---|---|
| Belt | Belt | Blade Type End |
| Air Bearing | Air Bearing | Effector |

| | | |
|---|---|---|
| Tilt | Tilt | b) Leading Edge |
| Directed | Directed | Extraction |

| | | |
|---|---|---|
| Airflow | Airflow | Vacuum Grip |

| | | |
|---|---|---|
| b) Panel Guide Means | Rollers | Edge Grip |

| | |
|---|---|
| Belt | b) Panel Guide Means |

| | |
|---|---|
| Air Bearing | Belt |
| Rollers | Air Bearing |

| | |
|---|---|
| c) Panel Support Means | Rollers |

| | |
|---|---|
| Belt | c) Panel Support |
| Air Bearing | Means |

| | |
|---|---|
| Rollers | Belt |

Air Bearing
Rollers

TABLE 2
INTERNAL TRANSFER FRAME DRIVE/GUIDANCE MEANS

| | | |
|---|---|---|
| 1. Drive and Guidance | 2. Guidance Means | 3. Synchronization |
| Means | Only | Means |
| a) Coupled to Door | a) Linear Slides | a) Coupled to |

| | | |
|---|---|---|
| Slit/Slot Opening at | Side Mounted | Container Door Drive |

| | | |
|---|---|---|
| Front | Rear Mounted | Belts/Pulleys |

| | | |
|---|---|---|
| b) Synchronous Spool | b) Cam Follower | Rack and Pinion |
| Type Support From | | |
| Top (One or More) | | |

Cable
Belt
Band

c) Synchronous
Closed Loop
Support (One
or More)

Cable
Belt
Band

TABLE 3
CONTAINER DOOR OPENING/DRIVE MEANS

| | |
|---|---|
| 1. Door Opening Means | 2. Door Drive Means |
| a) Front Opening Door | a) Container Integrated Door Drive |

| | |
|---|---|
| Indexing Slit Opening | Motor with belt/pulley drive |
| Complete Upward | to rollers |
| Opening | Roller direct drive motor |
| Complete Downward | Coupling to internal transfer |
| Opening | frame |

| | |
|---|---|
| b) Front and Bottom Opening | b) External Door Drive |

| Door | | Loadport |
|---|---|---|
| | One Piece Door | Cassette Station Interface |

| | |
|---|---|
| Wrap Around | Coupling to external transfer |
| Upward Opening | frame |
| Wrap Around | |
| Downward Opening | |

Two Piece Doors that
Open in Opposite Directions

TABLE 4
CONTAINER PANEL INDEXING MEANS

| 1. Container Fixed Height/Panel Transfer | | 2. Container Indexing In “Z”/Panel |
|---|---|---|
| Robot Indexes in “Z” | | Transfer Robot Fixed Height |
| a) Internal Transfer Frame Indexing Means | | a) Internal Transfer Frame Support |
| | Z Post Type Coupled From Below | Means |

| | |
|---|---|
| 1 or more posts | Z-Post Type Coupled From |

| | |
|---|---|
| Slit Door Opening Frame | Below |

| | |
|---|---|
| Container Side Slot Coupling to | 1 or more posts |

| | External Drive | Slit Opening Door Frame |
|---|---|---|
| | Container Internally Integrated Drive | Container Side Slot Coupling to |
| | (motor, etc.) | External Drive |
| | Cassette Transfer Station Front | Container Internally Integrated |
| | Coupled Drive | Drive (motor, etc.) |
| b) External Transfer Frame Indexing Means | | Cassette Transfer Station Front |
| | Frame Parked Below Container | Coupled Drive |

| | |
|---|---|
| Transfer Station Front Coupled | b) External Transfer Frame Indexing |
| Drive | Means |

| | |
|---|---|
| Bottom Coupled Drive | Frame Parked Below Container |

| | |
|---|---|
| Scissor Lift | Transfer Station Front |

| | |
|---|---|
| Frame Parked in Cassette Station | Coupled Drive |
| Cassette | Bottom Coupled Drive |

| | |
|---|---|
| Extends From Cassette Station | Scissor Lift |

| | |
|---|---|
| Under Front of Container | Frame Parked in Cassette Station |

| | |
|---|---|
| c) Transfer Robot With Blade Type End | Cassette |

| Effector Provides Indexing | Extends From Cassette |
|---|---|
| | Station Under Front of |
| | Container |

It should be appreciated that the above-described container and isolation systems are for explanatory purposes only and that the invention is not limited thereby. Having thus described a preferred embodiment of a container and system for storing, transporting and loading large area substrates or wafers, it should be apparent to those skilled in the art that certain advantages of the within system have been achieved. It should also be appreciated that various modifications, adaptations, and alternative embodiments thereof may be made within the scope and spirit of the present invention. For example, the container and system may also be used to store other types of substrates or be used in connection with other equipment within a semiconductor manufacturing facility. It should be appreciated that many of the inventive concepts described above would be equally applicable to the use of non-semiconductor manufacturing applications as well as semiconductor related manufacturing applications. Exemplary uses of the inventive concepts may be integrated into solar cell manufacturing and related manufacturing technologies, such as; single crystal silicon, polycrystalline silicon, thin film, and organic processes, etc.

Any of the operations described herein that form part of the invention are useful machine operations. The invention also relates to a device or an apparatus for performing these operations. The apparatus can be specially constructed for the required purpose, or the apparatus can be a general-purpose computer selectively activated, implemented, or configured by a computer program stored in the computer. In particular, various general-purpose machines can be used with computer programs written in accordance with the teachings herein, or it may be more convenient to construct a more specialized apparatus to perform the required operations.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims. In the claims, elements and/or steps do not imply any particular order of operation, unless explicitly stated in the claims.

1. A container for supporting substrates for processing, comprising:
a base, a top, and side panels connecting the base and the top,
a support structure disposed in the container, the support structure configured to support the substrates within the container, the support structure having rows of multiple tensile members extending across a width of the container, each row of the multiple tensile members configured to support a substrate, wherein one of the side panels includes a moveable flexible membrane enabling access into the container, a support structure of the flexible membrane having a synchronization mechanism for synchronizing movement of the flexible membrane with a door of a receiving module of a processing tool.

2. The container of claim 1, further comprising:
vertical support members extending from one of the base or the top, the vertical support members having ends of the multiple tensile members affixed thereto, wherein the vertical support members are within an inner area of the container.

3. The container of claim 2, further comprising;
a transfer member having outer supports disposed external to the inner area and inner supports affixed to the outer supports, the inner supports extending across the width of the container.

4. The container of claim 3, wherein the transfer member is moveable along a height of the container.

5. The container of claim 1, wherein the base is a flexible membrane enabling access into the container.

6. The container of claim 1, wherein the flexible membrane is connected to rigid supports at opposing ends of the flexible membrane, the rigid supports each having ends attached to the synchronization mechanism.

7. The container of claim 6, further comprising:
first and second belts having ends affixed to corresponding ends of first and second rigid supports.

8. The container of claim 1, wherein the synchronization mechanism includes a receptacle for a pin extending from a door of the receiving module.

9. The container of claim 1, wherein the container includes a fan and filter assembly affixed to one of the side panels.

10. The container of claim 1, wherein the flexible membrane has a slot extending therethrough, the slot enabling access of a substrate into and out of the container.

11. The container of claim 1, further comprising:
rollers extending across edges of the container, wherein the rollers guide the flexible membrane as the flexible membrane moves.

12. The container of claim 1, wherein the tensile members are hollow members having apertures along a top surface of each of the tensile members.

13. The container of claim 1, wherein the base includes a plurality of openings extending across the width of the container, the plurality of openings having moveable doors opening and closing access thereto.

14. A system for transporting substrates, comprising:
a container for supporting substrates for processing, the container including a base, a top, and side panels connecting the base and the top, the container further including a support structure disposed in the container, the support structure configured to support the substrates within the container, the support structure having rows of multiple tensile members extending across a width of the container, each row of the multiple tensile members configured to support a substrate, wherein one of the side panels includes a moveable flexible membrane enabling access into the container; and
a substrate transfer station configured to access the substrates through the and access area enabled by the flexible membrane.

15. The system of claim 14, wherein the base is another moveable flexible membrane.

16. The system of claim 14, wherein the substrate transfer station is disposed below the container.

17. The system of claim 16, wherein the base includes a plurality of openings having moveable doors enabling access into the container, and wherein the substrate transfer station includes a plurality of posts aligned with corresponding openings, the plurality of posts configured to lift the substrates from the tensile members.

18. The system of claim 17, wherein the plurality of posts have a top surface comprising one of a roller, a belt or an air bearing.

19. The system of claim 16, wherein the substrate transfer station is fixed in position and the container is movably disposed over the substrate transfer station.

20. The system of claim 14 wherein the substrate transfer station includes a transfer robot having an extendible element configured to enter the container through the access enabled by the flexible membrane.

21. The system of claim 14, wherein the substrate transfer station includes another flexible membrane corresponding to the flexible membrane on the container, the another flexible membrane and the flexible membrane on the container synchronized to move in unison.

22. The system of claim 21 wherein a support for the flexible membrane includes a receptacle configured to receive an extension member of a support of the another membrane.

23. The system of claim 16, wherein the flexible membrane includes a slot opening, and wherein movement of the flexible membrane with vertical movement of the container relative to the substrate transfer station.

24. The system of claim 16, wherein the substrate transfer station is contained within a housing, the housing having a plurality of openings on a top surface enabling posts of the substrate transfer system access to the substrates.

25. A container for supporting semiconductor processing substrates, comprising:
a base, a top, and side panels connecting the base and the top;
a support structure disposed in the container, the support structure configured to support the substrates within the container, the support structure having an array arranged in rows and columns of multiple tensile members extending across a width of the container, each row of the multiple tensile members configured to support a substrate, wherein one of the side panels includes a moveable flexible membrane enabling access into the container; and
a rotating member extending across an edge of the one of the side panels, the rotating member guiding the flexible membrane during movement.

26. The container of claim 25, wherein a path of the flexible membrane during the movement is external to one of a top surface or a bottom surface of the container.

27. The container of claim 25, wherein the top has a plurality of apertures defined therethrough and wherein the moveable flexible membrane retracts over the top when enabling access into the container.

28. The container of claim 25, wherein the rotating member is a spring loaded tension roller.

29. A container for supporting semiconductor processing substrates, comprising:
a base, a top, and side panels connecting the base and the top;
a support structure disposed in the container, the support structure configured to support the substrates within the container, the support structure having an array arranged in rows and columns of multiple tensile members extending across a width of the container, each row of the multiple tensile members configured to support a substrate, wherein one of the side panels and the base includes a moveable flexible membrane enabling access into the container from both the base and the one of the side panels.

30. The container of claim 29, further comprising:
a panel transfer paddle disposed within the container, the panel transfer paddle configured to move vertically within the container to assist in transporting the substrates.

31. The container of claim 29, wherein independent moveable flexible membranes enable access into the container from the base and the one of the side panels.
